(19) United States
(12) Patent Application Publication
(10) Pub. No.: US 2026/0271650 A1
(43) Pub. Date: Sep. 10, 2026

(54) SYSTEMS AND APPARATUS FOR CONTROLLING FLUID FLOW

(71) Applicant: Ichor Systems, Inc., Fremont, CA (US)

(72) Inventors: Randolph Treur, San Luis Obispo, CA (US); Michael Vogtmann, Templeton, CA (US); Stephen Carson, Woodstock, NY (US); Philip Ryan Barros, Pleasanton, CA (US); Sean Joseph Penley, Sparks, NV (US); Zachariah Ezekiel McIntyre, Reno, NV (US)

(73) Assignee: Ichor Systems, Inc., Fremont, CA (US)

(21) Appl. No.: 19/557,855

(22) Filed: Mar. 5, 2026

Related U.S. Application Data
(60) Provisional application No. 63/768,324, filed on Mar. 7, 2025.

(51) Int. Cl. H10P 72/00; F15D 1/02

(52) U.S. Cl. CPC H10P 72/0402; F15D 1/025

(57) ABSTRACT

Systems for processing articles are essential for semiconductor fabrication. These systems employ a variety of apparatuses for controlling flow. In one implementation, an apparatus for controlling flow may utilize a body having a flow path extending from an inlet to an outlet. A valve, a flow restrictor, and a pressure sensor are operably coupled to the flow path. The flow restrictor incorporates a restriction path and grooves on the outer circumference which enable pressure sensing when the flow restrictor is positioned immediately adjacent a seat of the valve.

### CROSS-REFERENCE TO RELATED APPLICATIONS

This application claims the benefit of U.S. Provisional Application 63/768,324, filed Mar. 7, 2025, which is incorporated herein by reference in its entirety.

### BACKGROUND OF THE INVENTION

Mass flow control has been one of the key technologies used in semiconductor chip fabrication. Apparatuses for controlling mass flow are important for delivering known flow rates of process gases and liquids for semiconductor fabrication and other industrial processes. Such devices are used to measure and accurately control the flow of fluids for a variety of applications. In a given fabrication tool, processing systems of the fabrication tool incorporates a variety of apparatuses for controlling flow to deliver a variety of liquids and gases. As a result, efficient gas and liquid handling is essential to modern semiconductor fabrication equipment.

As the technology of chip fabrication has improved, so has the demand on the apparatuses for controlling flow. Semiconductor fabrication processes increasingly require increased performance, a greater range of flow capability, more process gases and liquids, and more compact installation of the necessary equipment. Improved gas and liquid handling for a variety of fluids is desirable, particularly enhanced performance in reduced physical space.

### SUMMARY OF THE INVENTION

The present technology is directed to systems for processing articles such as semiconductors. In other embodiments, the present technology is directed to apparatuses for controlling flows of process fluids. In yet other embodiments, the present technology is directed to flow restrictors which may be used in the aforementioned systems and apparatuses. The present systems, apparatuses, and flow restrictors may be used in a wide range of processes such as semiconductor chip fabrication, solar panel fabrication, etc.

In one implementation, the invention is a system for processing articles. The system has a fluid supply, an apparatus for controlling flow fluidly coupled to the fluid supply, and a processing chamber fluidly coupled to an outlet of the apparatus for controlling flow. The processing chamber is configured to process semiconductor devices. The apparatus for controlling flow has a body, a valve, a flow restrictor, and a pressure sensor. The body has a flow path extending from an inlet to the outlet. The valve is operably coupled to the flow path between the inlet and the outlet, the valve configured to alter fluid flow within the flow path. The valve has a seat and a closure member. The flow restrictor has a flow impedance and is located within the flow path. The flow restrictor has a restriction path extending from a first end to a second end along a longitudinal axis, a circumferential groove, and a longitudinal groove extending from the circumferential groove to the first end. The pressure sensor is configured to measure pressure within a volume between the seat of the valve and the flow restrictor.

In another implementation, the invention is an apparatus for controlling flow. The apparatus for controlling flow has a body, a valve, a flow restrictor, and a pressure sensor. The body has a flow path extending from an inlet to an outlet. The valve is operably coupled to the flow path between the inlet and the outlet, the valve configured to alter fluid flow within the flow path. The valve has a seat and a closure member. The flow restrictor has a flow impedance and is located within the flow path. The flow restrictor has a restriction path extending from a first end to a second end along a longitudinal axis, a circumferential groove, and a longitudinal groove extending from the circumferential groove to the first end. The pressure sensor is configured to measure pressure within a volume between the seat of the valve and the flow restrictor.

In yet another implementation, the invention is a flow restrictor for controlling flow. The flow restrictor has a body extending from a first end to a second end along a longitudinal axis. The body has an outer surface having a sealing portion configured to engage a passage of a valve. The flow restrictor also has a restriction path extending from the first end to the second end along the longitudinal axis.

Further areas of applicability of the present technology will become apparent from the detailed description provided hereinafter. It should be understood that the detailed description and specific examples, while indicating the preferred implementation, are intended for purposes of illustration only and are not intended to limit the scope of the technology.

### BRIEF DESCRIPTION OF THE DRAWINGS

The invention of the present disclosure will become more fully understood from the detailed description and the accompanying drawings, wherein:

FIG. 1 is a schematic of a processing system for manufacturing semiconductor devices utilizing one or more apparatuses for controlling flow.

FIG. 2 is a schematic of a mass flow controller, the mass flow controller being one of the apparatuses for controlling flow as may be utilized in the process of FIG. 1.

FIG. 3 is a schematic of an alternate configuration of a mass flow controller as may be utilized in the process of FIG. 1.

FIG. 4 is a perspective view of a mass flow controller as may be utilized in the system of FIG. 1.

FIG. 5 is an exploded view of the mass flow controller.

FIG. 6 is a cross-sectional view of the mass flow controller taken along line 6-6 of FIG. 4.

FIG. 7 is a perspective view of a first embodiment of a flow restrictor as may be utilized in the mass flow controller of FIG. 4.

FIG. 8 is a top view of the flow restrictor.

FIG. 9A is a cross-sectional view of the flow restrictor taken along line 9A-9A of FIG. 8.

FIG. 9B is a detail view of area 9B of FIG. 9A.

FIG. 10 is a cross-sectional view of the flow restrictor taken along line 10-10 of FIG. 9A.

FIG. 11 is a perspective view of a second embodiment of a flow restrictor as may be utilized in the mass flow controller of FIG. 4.

FIG. 12 is a top view of the flow restrictor.

FIG. 13A is a cross-sectional view of the flow restrictor taken along line 13A-13A of FIG. 12.

FIG. 13B is a detail view of area 13B of FIG. 13A.

FIG. 14 is a cross-sectional view of the flow restrictor taken along line 14-14 of FIG. 13A.

FIG. 15 is a perspective view of a third embodiment of a flow restrictor as may be utilized in the mass flow controller of FIG. 4.

FIG. 16 is a top view of the flow restrictor.

FIG. 17A is a cross-sectional view of the flow restrictor taken along line 17A-17A of FIG. 16.

FIG. 17B is a detail view of area 17B of FIG. 17A.

FIG. 18 is a cross-sectional view of the flow restrictor taken along line 18-18 of FIG. 17A.

FIG. 19 is a perspective view of a fourth embodiment of a flow restrictor as may be utilized in the mass flow controller of FIG. 4.

FIG. 20 is a top view of the flow restrictor.

FIG. 21A is a cross-sectional view of the flow restrictor taken along line 21A-21A of FIG. 20.

FIG. 21B is a detail view of area 21B of FIG. 21A.

FIG. 22 is a cross-sectional view of the flow restrictor taken along line 22-22 of FIG. 21A.

FIG. 23 is a perspective view of a fifth embodiment of a flow restrictor as may be utilized in the mass flow controller of FIG. 4.

FIG. 24 is a top view of the flow restrictor.

FIG. 25A is a cross-sectional view of the flow restrictor taken along line 25A-25A of FIG. 24.

FIG. 25B is a detail view of area 25B of FIG. 25A.

FIG. 26 is a cross-sectional view of the flow restrictor taken along line 26-26 of FIG. 25A.

FIG. 27 is a perspective view of a sixth embodiment of a flow restrictor as may be utilized in the mass flow controller of FIG. 4.

FIG. 28 is a top view of the flow restrictor.

FIG. 29A is a cross-sectional view of the flow restrictor taken along line 29A-29A of FIG. 28.

FIG. 29B is a detail view of area 29B of FIG. 29A.

FIG. 30 is a cross-sectional view of the flow restrictor taken along line 30-30 of FIG. 29A.

### DETAILED DESCRIPTION

The description of illustrative embodiments according to principles of the present invention is intended to be read in connection with the accompanying drawings, which are to be considered part of the entire written description. In the description of embodiments of the invention disclosed herein, any reference to direction or orientation is merely intended for convenience of description and is not intended in any way to limit the scope of the present invention. Relative terms such as “lower,” “upper,” “horizontal,” “vertical,” “above,” “below,” “up,” “down,” “left,” “right,” “top” and “bottom” as well as derivatives thereof (e.g., “horizontally,” “downwardly,” “upwardly,” etc.) should be construed to refer to the orientation as then described or as shown in the drawing under discussion. These relative terms are for convenience of description only and do not require that the apparatus be constructed or operated in a particular orientation unless explicitly indicated as such. Terms such as “attached,” “affixed,” “connected,” “coupled,” “interconnected,” and similar refer to a relationship wherein structures are secured or attached to one another either directly or indirectly through intervening structures, as well as both movable or rigid attachments or relationships, unless expressly described otherwise. Moreover, the features and benefits of the invention are illustrated by reference to the preferred embodiments. Accordingly, the invention expressly should not be limited to such preferred embodiments illustrating some possible non-limiting combinations of features that may exist alone or in other combinations of features; the scope of the invention being defined by the claims appended hereto.

The present invention is directed to systems for processing articles, these systems having apparatuses for controlling fluid flow. In some embodiments, the apparatus may function as a mass flow controller to deliver a known mass flow of gas or liquid to a semiconductor or similar process. Semiconductor fabrication is one industry which demands high performance in control of fluid flows. As semiconductor fabrication techniques have advanced, customers have recognized the need for flow control devices with increased accuracy and repeatability in the mass of the delivered fluid flows. Such flow control devices rely on flow restrictors having improved accuracy, reduced cost of manufacture, and greater functionality. The present systems enable improved systems for processing articles by utilizing improved flow restrictors and apparatuses incorporating flow restrictors.

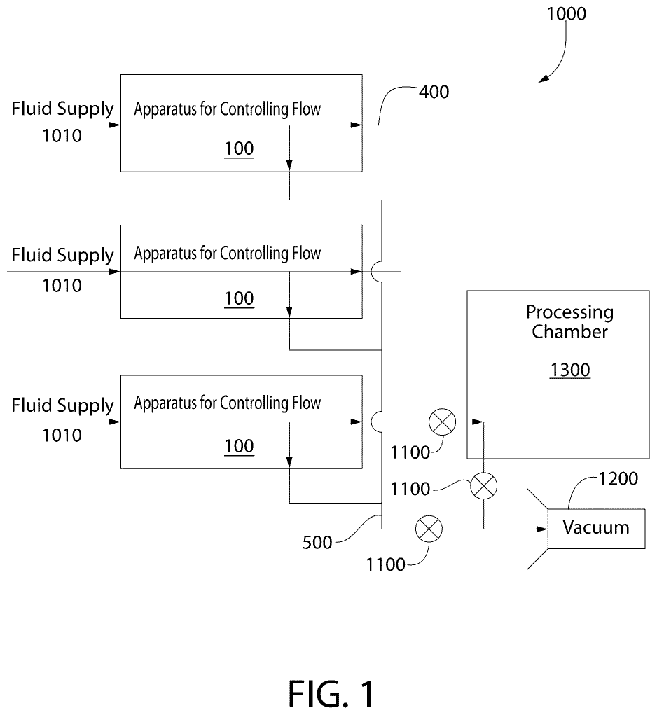

FIG. 1 shows a schematic of an exemplary processing system 1000 for processing articles. The processing system 1000 may utilize a plurality of apparatus for controlling flow 100 fluidly coupled to a processing chamber 1300. Each of the plurality of apparatus for controlling flow 100 has a fluid supply 1010 fluidly coupled thereto, each of the fluid supplies 1010 supplying a process fluid to their respective apparatuses for controlling flow 100. Optionally, a plurality of fluid supplies 1010 may be fluidly coupled to a single apparatus for controlling flow 100 or a plurality of apparatuses for controlling flow 100 may be fluidly coupled to a single fluid supply 1010. Each of the fluid supplies 1010 may deliver a different process fluid or a portion of the fluid supplies 1010 may deliver a single process fluid.

The plurality of apparatus for controlling flow 100 are used to supply one or more different process fluids to the processing chamber 1300 via an outlet manifold 400. Articles such as semiconductors may be processed within the processing chamber 1300. A valve 1100 isolates the apparatuses for controlling flow 100 from the processing chamber 1300, enabling the apparatuses for controlling flow 100 to be selectively connected or isolated from the processing chamber 1300. The processing chamber 1300 may contain one or more applicators to apply process fluids delivered by the plurality of apparatus for controlling flow 100, enabling selective or diffuse distribution of the fluid supplied by the plurality of apparatus for controlling flow 100.

In addition, the processing system 1000 may further comprise a vacuum source 1200 which is isolated from the processing chamber 1300 by a valve 1100 to enable evacuation of process fluids or facilitate purging one or more of the apparatus for controlling flow 100 to enable switching between process fluids in the same apparatus for controlling flow 100. Each of the apparatuses for controlling flow 100 may have a separate bleed port which is coupled to a vent manifold 500, the vent manifold 500 connected to the vacuum source 1200 via a valve 1100. Optionally, the apparatuses for controlling flow 100 may be mass flow controllers, flow splitters, or any other device which controls the flow of a process fluid in a processing system. Furthermore, valves 1100 may be integrated into the apparatus for controlling flow 100 if so desired. In some implementations this may eliminate the need for certain other valves 1100 in the processing system 1000.

Processes that may be performed in the processing system 1000 may include wet cleaning, photolithography, ion implantation, dry etching, atomic layer etching, wet etching, plasma ashing, rapid thermal annealing, furnace annealing, thermal oxidation, chemical vapor deposition, atomic layer deposition, physical vapor deposition, molecular beam epitaxy, laser lift-off, electrochemical deposition, chemical-mechanical polishing, wafer testing, or any other process utilizing controlled volumes of a process fluid.

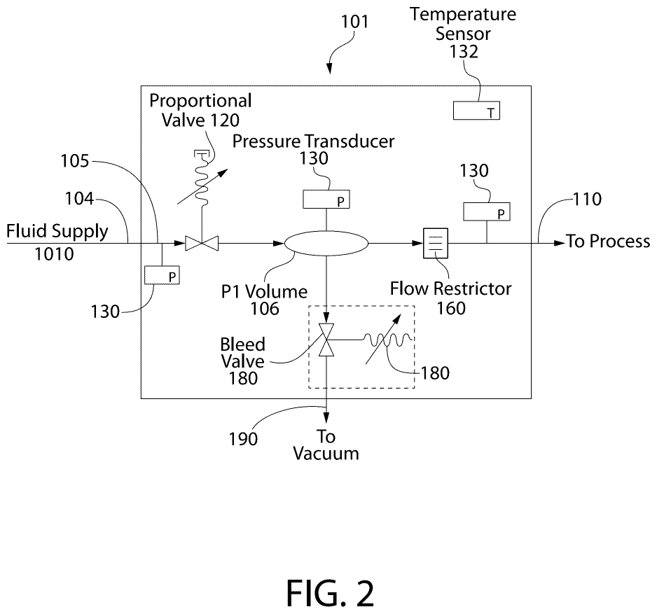

FIG. 2 shows a schematic of an exemplary mass flow controller 101, which is one type of apparatus for controlling flow 100 that may be utilized in the processing system 1000. The mass flow controller 101 has a fluid supply 1010 of a process fluid fluidly coupled to an inlet 104. A fluid pathway 105 extends from the inlet 104 to an outlet 110, the outlet 110 fluidly coupled to the outlet manifold 400. The inlet 104 is fluidly coupled to a proportional valve 120 which is capable of varying the mass and volume of process fluid flowing through the proportional valve 120. The proportional valve 120 meters the mass flow of process fluid which passes to a P1 volume 106. The proportional valve 120 is capable of providing proportional control of the process fluid such that it need not be fully open or closed, but instead may have intermediate states to permit control of the mass flow rate of process fluid.

The P1 volume 106 is fluidly coupled to the proportional valve 120, the P1 volume 106 being the sum of all the volume within the mass flow controller 101 between the proportional valve 120 and a flow restrictor 160. In particular, the P1 volume 106 is the volume between the seat of the proportional valve 120 and the flow restrictor 160 as will be discussed in greater detail below. A pressure transducer 130 is fluidly coupled to the P1 volume 106 to enable measurement of the pressure within the P1 volume 106. A second pressure transducer 130 is fluidly coupled to the outlet 110 to enable measuring the pressure differential across the flow restrictor 160.

Optionally, a shutoff valve may be used to completely halt flow of the process fluid. The shutoff valve may be located upstream, downstream, or within the mass flow controller 101. In a preferred implementation, the proportional valve 120 also serves as a shutoff valve capable of halting fluid flow. Preferably, the shutoff valve has a leakage rate across the valve seat of less than or equal to 1E-9 atm cc He/sec at room temperature, less than or equal to 1E-7 atm cc He/sec at 200 degrees Celsius or less, and less than or equal to 1E-6 atm cc He/sec at 300 degrees Celsius or less. Each of these values are for a 30 pound per square inch gauge pressure across the valve seat. The maximum allowable leak rate must be held for at least 15 seconds before Helium completely permeates through the seat material. The flow restrictor 160 is fluidly coupled to the outlet 110 of the mass flow controller 101. In the processing system, the outlet 110 is fluidly coupled to a valve 1100 or directly to the processing chamber 1300.

Finally, an optional bleed valve 180 may be coupled to the P1 volume 106 and to a bleed port 190. In the present example, the bleed valve 180 is a proportional valve. The bleed valve 180 may also be an on/off valve or any other type of valve suitable for controlling fluid flow. Optionally, a second flow restrictor 160 may be incorporated between the P1 volume and the bleed port 190. A proportional valve, if used as the bleed valve 180, enables control over a rate of fluid flow through the bleed port 190. A characterized restrictor 160 may aid in improving control over the rate of fluid flow, regardless of whether the bleed valve 180 is a proportional valve or an on/off valve. Preferably, the rate of fluid flow through the bleed valve 180 is characterized so that the flow rate can be estimated for a given state of the bleed valve 180. However, the bleed valve 180 and the bleed port 190 may be omitted as desired.

Internal to the proportional valve 120 is a valve seat and a closure member. When the apparatus 100 is delivering process fluid, the proportional valve 120 is in an open state, such that the valve seat and the closure member are not in contact. As discussed below, the open state includes all positions where the valve seat and the closure member are not in contact. The proportional valve 120 may vary the distance between the valve seat and the closure member to vary the rate of fluid flow through the proportional valve 120 or control pressure upstream or downstream of the proportional valve. When the proportional valve 120 is in a closed state the closure member and the valve seat are biased into contact by a biasing element such as a spring, stopping the flow of process fluid through the proportional valve 120. The operation of the proportional valve 120 will be discussed in greater detail below.

The flow restrictor 160 is used, in combination with the proportional valve 120, to meter flow of the process fluid. In most embodiments, the flow restrictor 160 provides a known restriction to fluid flow. The first characterized flow restrictor 160 may be selected to have a specific flow impedance to enable delivery of a desired range of mass flow rates of a given process fluid. The flow restrictor 160 has a greater resistance to flow than the passages upstream and downstream of the flow restrictor 160.

Optionally, the mass flow controller 101 comprises one or more P0 pressure transducers between the inlet 104 and the P1 volume 106. Preferably, the P0 pressure transducer, if implemented, is located between the inlet 104 and the proportional valve 120. Optionally, the mass flow controller 101 also comprises one or more P2 pressure transducers downstream of the flow restrictor 160. Preferably, the P2 pressure transducer, if implemented, is located between the outlet 110 and the flow restrictor 160. The P0, P1, and P2 pressure transducers may be used to measure the pressure differential across the flow restrictor 160 or the proportional valve 120. In some embodiments, readings of the pressure between the flow restrictor 160 and the outlet 110 may be obtained from another apparatus 100 connected to the processing chamber, with the readings communicated to the mass flow controller 101. In other embodiments, readings of the pressure between the proportional valve 120 and the inlet 104 may be obtained from another apparatus 100 connected to the fluid supply 1010.

Optionally, one or more temperature sensors 132 may be employed to further enhance the accuracy of the mass flow controller 101. They may be mounted in the base of the mass flow controller 101 near the P1 volume 106. Additional temperature sensors 132 may be employed in a variety of locations, including adjacent the proportional valve 120, the pressure transducer 130, and the bleed valve 180.

The proportional valve 120, the shutoff valve (if separately equipped), and the bleed valve 180 may be referred to as active components because they are actively controlled to achieve the desired control of fluids through the plurality of apparatus for controlling flow 100. The active components need not be valves, and may also include devices which selectively restrict flow, or otherwise alter a characteristic of the fluid flowing through the apparatus for controlling flow. Other types of active components may be flow regulators, transducers, or actuators.

The pressure transducer 130 and the temperature sensors 132 may be referred to as sensors because they detect or sense a characteristic of a fluid within a fluid pathway 105 of the plurality of apparatus for controlling flow 100. In other implementations, the pressure transducer 130 or the temperature sensor 132 may be used to sense a characteristic of a fluid within the system, but external to the plurality of apparatus for controlling flow. For example, when two apparatus for controlling flow are fluidly coupled by the outlet manifold 400, a pressure within one apparatus for controlling flow can be measured by a pressure transducer located within a second apparatus for controlling flow. Other types of sensors may include transducers, flow sensors, accelerometers, gyroscopes, or any other known device for sensing a characteristic within the system including characteristics of the fluids or characteristics of the apparatus for controlling flow 100.

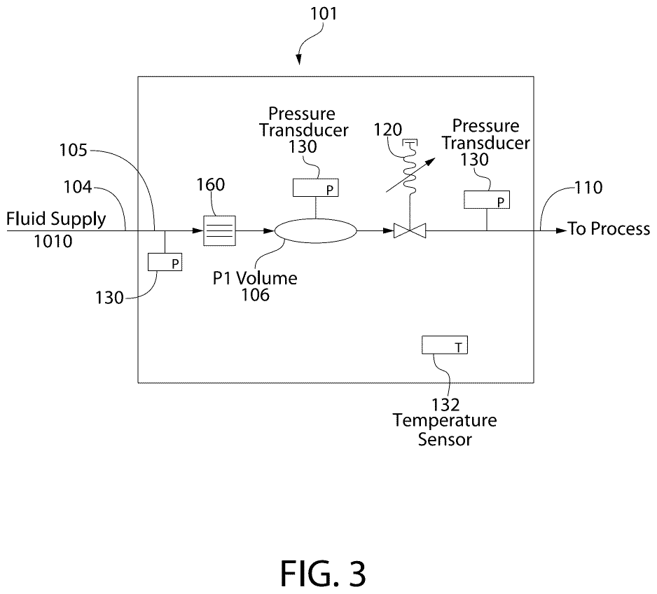

In other implementations, such as that shown in FIG. 3, the mass flow controller 101 may utilize an alternate configuration where the flow restrictor 160 is fluidly coupled to the inlet 104, the inlet 104 fluidly coupled to the fluid supply 1010. The flow restrictor 160 is fluidly coupled to the proportional valve 120, with the P1 volume 106 located between the flow restrictor 160 and the seat of the proportional valve 120. A first pressure transducer 130 is fluidly coupled to the fluid supply 1010. A second pressure transducer 130 is fluidly coupled to the P1 volume 106 so that it senses pressure within the P1 volume 106. A third pressure transducer 130 serves as a P2 pressure transducer to sense pressure between the proportional valve 120 and the outlet 110. As noted above, the proportional valve 120 may function as an on/off valve or separate on/off valve may be fitted to the mass flow controller 101. In yet further configurations, an on/off valve may be located upstream or downstream of the mass flow controller 101.

Optionally, a bleed valve 180 may be included or omitted in the mass flow controller 101 of FIG. 3. Further optionally, the first and third pressure transducers 130 may be omitted or located elsewhere. The proportional valve 120 may be substituted with an on/off valve, and the location of the proportional valve 120 and the flow restrictor 160 may be switched. In yet other implementations, the valve 1100 may be used in place of the on/off valve 150.

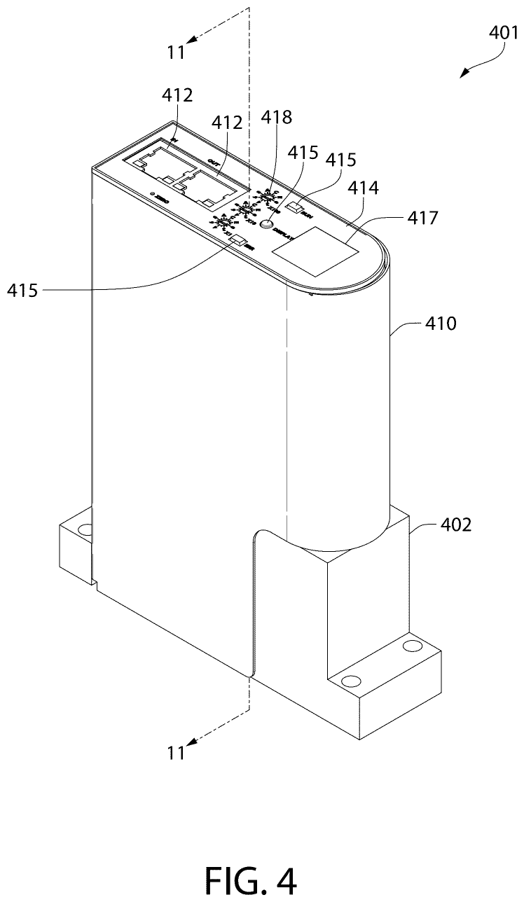

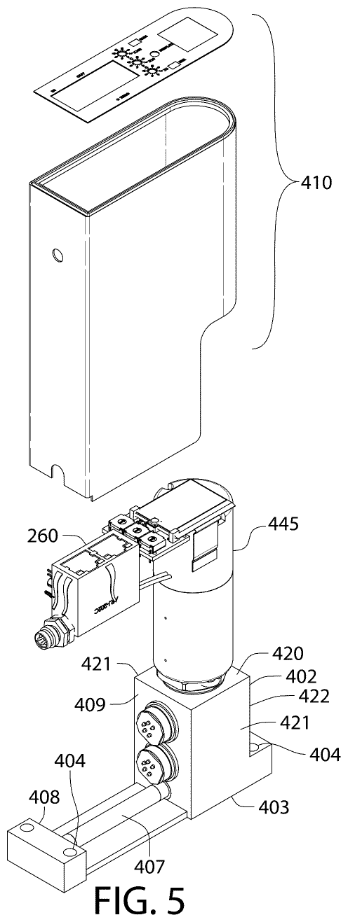

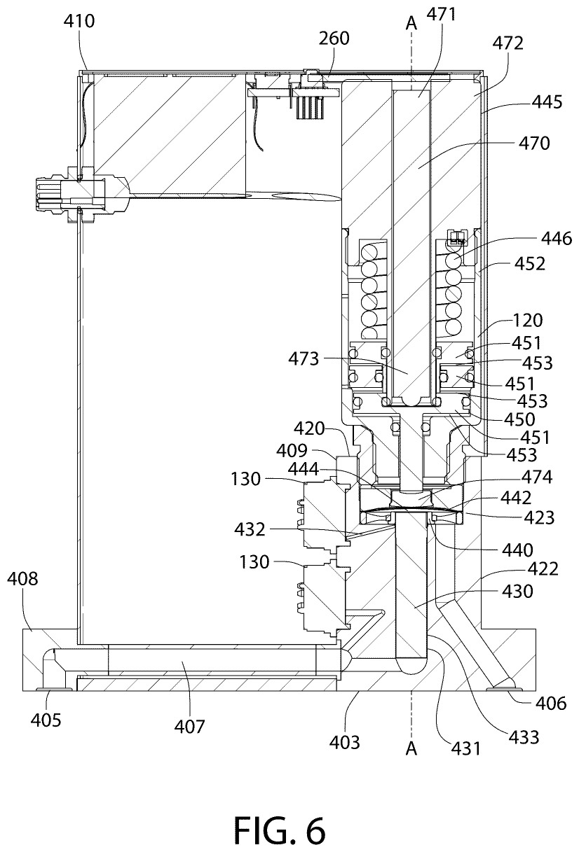

FIGS. 4 and 5 illustrate a mass flow controller 401 which is one of the potential apparatuses for controlling flow 100 that may be used in the processing system 1000. The mass flow controller 401 has a body 402 which receives one or more components. A housing 410 is coupled to the body 402, the housing covering the components which are mounted to the body 402. The housing 410 may have provisions for one or more connectors 412 and a user interface 414. Preferably, the housing 410 is formed of sheet metal and is detachably coupled to the body 402 to allow servicing of the mass flow controller 401. The user interface 414 may include buttons 415, indicators, a display 417, and one or more variable input devices 418 such as potentiometers or encoders.

The body 402 may incorporate a mounting surface 403 and a plurality of mounting apertures 404 configured to allow mounting of the body 402 to a substrate component, fluid fitting, substrate, or other component. The mounting apertures 404 may permit the passage of fasteners such as bolts or may be formed in other shapes suitable to receive clips or other known fasteners. The mounting surface 403 has an inlet 405 and an outlet 406 formed therein. A flow path 407 for fluid extends from the inlet 405 to the outlet 406. Optionally, the body 402 may include a first extension 408, the inlet 405 formed in the first extension 408. The first extension 408 includes a portion of the flow path 407, the first extension 408 forming a portion of the mounting surface 403.

The inlet 405 and outlet 406 may incorporate seal cavities to receive seals or may be configured to allow welding or adhesive attachment of fittings or other components instead of seal cavities. In addition, the inlet 405 and the outlet 406 may not be formed into the mounting surface 403, instead being formed into another surface of the body 402, particularly where fittings are used instead of seal cavities.

The body 402 further incorporates an interior surface 409, a top surface 420, side surfaces 421, and a rear surface 422. Optionally, the interior surface 409 or the side surfaces 421 may receive one or more pressure sensors 130 or temperature sensors 132. The top surface 420 may incorporate a cavity 423 which receives the valve 120. The cavity 423 may receive various components of the valve 120 as will be discussed below. A flow restrictor 430 may also be at least partially located within the cavity 423, the flow restrictor 430 located within the flow path 407 and immediately adjacent the seat 440 of the valve 120. The flow restrictor 430 provides a flow impedance to fluid flow. The flow restrictor 430 may be located within a recess 431 of the flow path 407 formed in the body 402, the flow restrictor 430 engaging a wall 433 of the recess 431. Preferably, the recess 431 or the seat 440 provides a seal to prevent fluid bypassing the flow restrictor 430 within the flow path 407.

The mass flow controller 401 also incorporates the device controller 260 as discussed above. The device controller 260 may be located within the housing 410 and includes all electrical components, connectors, and other components required to interface with a central controller and operate the valve 120, pressure and temperature sensors 130, 132, and other devices within the mass flow controller 401.

In the mass flow controller 401, the flow restrictor 430 is located between the seat 440 of the valve 120 and the inlet 405 along the flow path 407. The valve 120 is located between the flow restrictor 430 and the outlet 406 along the flow path 407. However, the location of the valve 120 and the flow restrictor 430 may be reversed in other implementations as noted above.

The valve 120 further incorporates a closure member 442 which engages the seat 440. The closure member 442 may be a diaphragm or other element which prevents fluid flow when it is engaged with the seat 440. Thus, the valve 120 is configured to alter fluid flow within the flow path 407. The valve 120 may be a proportional valve capable of varying fluid flow. The valve 120 may also function as an on/off valve which completely halts the flow of fluid through the flow path 407. Flow through the valve 120 increases with increasing distance between the closure member 442 and the seat 440, and the distance may be varied to achieve the desired flow rate.

A first one of the pressure sensors 130 is fluidly coupled to the flow path 407 between the flow restrictor 430 and the inlet 405, allowing the pressure sensor 130 to sample the pressure of the fluid at the inlet 405. A second one of the pressure sensors 130 is fluidly coupled to a volume 444 defined between the seat 440 and the flow restrictor 430. A fluid connection path 432 is provided between the second one of the pressure sensors 130 coupled to the body 402 and the volume 444. The fluid connection path 432 is partially formed into the body 402 and partially formed by a groove in the flow restrictor 430, allowing fluid communication between the pressure sensor 130 and the volume 444 while minimizing the packaging size and the additional volume required to monitor pressure within the volume 444. The volume 444 is defined by the flow restrictor 430 and the portion of the flow path 407 extending to a surface of the seat 440 that is engaged by the closure member 442. Preferably, the volume 444 is less than 0.1 cubic centimeters. Further preferably, the volume 444 is less than 0.01 cubic centimeters.

Returning to the valve 120, a biasing element 446 provides a biasing force which biases the diaphragm into a normally closed position where the diaphragm 442 is in contact with the seat 440. The biasing force ends generally along a longitudinal axis A-A that extends through the seat 440. This causes the valve 120 to be in a closed state. The valve 120 further includes a first actuator 450 and a second actuator 470 that collectively form an actuator assembly 445. The first actuator 450 may be a pneumatic actuator, hydraulic actuator, motor and screw actuator, solenoid, linear motor, or other known type of actuator. The second actuator 470 may be a piezoelectric actuator, motor and screw actuator, linear motor, solenoid, or other known type of actuator. In other implementations, only a single actuator may be used, and may be any type of actuator.

The first actuator 450 may be a pneumatic actuator comprising one or more pistons 451 within a housing 452 of the valve 120. The pistons 451 and the housing 452 collectively form one or more chambers 453. The chambers 453 may be pressurized to apply a first force in a direction opposite the biasing force along the longitudinal axis A-A. The first force may be greater than the biasing force, causing the diaphragm 442 to be separated from the seat 440 by a first distance. The first force may be sufficient to move the pistons 451 against mechanical stops, limiting further upward travel away from the valve seat 440. Thus, placing the first actuator 450 in an active state may transition the valve 120 from the closed state to an open state, the open state occurring as soon as the closure member 442 is separated from the valve seat 440 by a non-zero distance.

The second actuator 470 may be a piezoelectric actuator or other actuator having a faster response time than the first actuator 450. The second actuator 470 is arranged in a generally cylindrical configuration, with a first end 471 coupled to a cap element 472 forming a part of the housing 452. The first end 471 may engage the cap element 472 via threads or may be contained within the cap element 472, providing a fixed end or travel limit for the second actuator 470. Extension of the second actuator 470 causes a second end 473 to move downward along the longitudinal axis A-A toward the valve seat 440. Thus, the second actuator 470 applies a second force which is in the same direction as the biasing force. The second actuator 470, when in an active state, causes the closure member 442 to move toward the seat 440. The second end 473 engages one of the pistons 451, which in turn engages a button 474 which engages the closure member 442. The second actuator 470 is placed in the active state by applying a drive voltage, with increasing drive voltages increasing the extension of the second actuator.

As can be seen, placing the second actuator 470 in an active state while the first actuator 450 is in an active state causes the distance between the closure member 442 and the seat 440 to be reduced. Placing the second actuator 470 in the active state while the first actuator 450 is in an inactive state will simply increase the compression force of the closure member 442 against the seat 440 and the distance will be zero. Placing the second actuator 470 in an inactive state while the first actuator 450 is in an active state will allow the distance between the closure member 442 and the seat 440 to be maximized, maximizing fluid flow.

During operation of the mass flow controller 401, the valve 120 may be controlled in two operating modes. Prior to operating in a first operating mode, the valve 120 is in a closed state and no fluid flows through the outlet 406. Upon receipt of a command to flow fluid at a predetermined flow rate, the valve 120 is transitioned to the open state. This is done by transitioning the first and second actuators 450, 470 to an active state. The position of the closure member 442 relative to the seat is then controlled based on position feedback provided by a position feedback sensor. The position feedback sensor may be a strain gauge, capacitive sensor, or any other known position feedback sensor. The position feedback sensor may be provided as a part of the second actuator 470 or separately installed in the valve 120.

In the first operating mode, the second actuator 470 is controlled based on position information provided by the position feedback sensor, but no feedback is provided with respect to the flow rate of fluid provided by the mass flow controller 401. The position of the closure member 442 of the valve 120 is determined based on a table, database, or formula which correlates the position to the desired mass flow rate. This table, database, or formula may be stored in the memory of either the central controller 200 or the device controller 260.

The first operating mode does not rely on feedback of the delivered mass flow rate to set the commanded position and operates in an open loop control mode. While there is position feedback to control the position of the closure member 442, there is no feedback for the mass flow rate of the fluid as mentioned above. Otherwise stated, the predetermined flow rate corresponds to a position setpoint, the position of the closure member 442 of the valve 120 driven to the position setpoint.

After a period of time, the valve 120 is transitioned to a second operating mode where the second actuator 470 is controlled based on feedback from the pressure sensor 130 which monitors pressure within the volume 444. The period of time may be predetermined or based on other factors. Optionally, feedback from the temperature sensor 132 and the first pressure sensor 130 which monitors pressure at the inlet 405 is also used to calculate the mass flow rate. The position of the closure member 442 is then adjusted based on feedback from the pressure sensor 130 to deliver the desired mass flow rate. Preferably, the valve 120 is controlled in the second operating mode once the fluid flow has approached steady state, avoiding control fluctuations resulting from fluctuations in the measured pressure of the fluid within the volume 444. When transitioning to the first operating mode, the first actuator 450 may be transitioned to the active state simultaneously with the second actuator 470, or the first actuator 450 may be transitioned to the active state before the second actuator 470 is transitioned to the active state.

In one implementation, the valve 120 is transitioned to the second operating mode when the pressure within the volume 106 stabilizes within a predetermined range. For example, the pressure may stabilize within 5 percent of a target pressure corresponding to the desired mass flow rate of the fluid being dispensed. Thus, instead of using a predetermined period of time, the time may be based on reaching a stable pressure measurement within the volume 106.

The configuration described above is only one exemplary configuration. Other configurations are contemplated. In another implementation, a single actuator may be used. Optionally, the biasing element 446 may be eliminated. Thus, the valve 120 may be normally closed or normally open. The actuator may operate to put the valve 120 in a closed state or may operate to put the valve 120 in an open state. The biasing element 446 may bias the valve 120 into the closed state or may be omitted and the actuator may drive the valve 120 to a closed state.

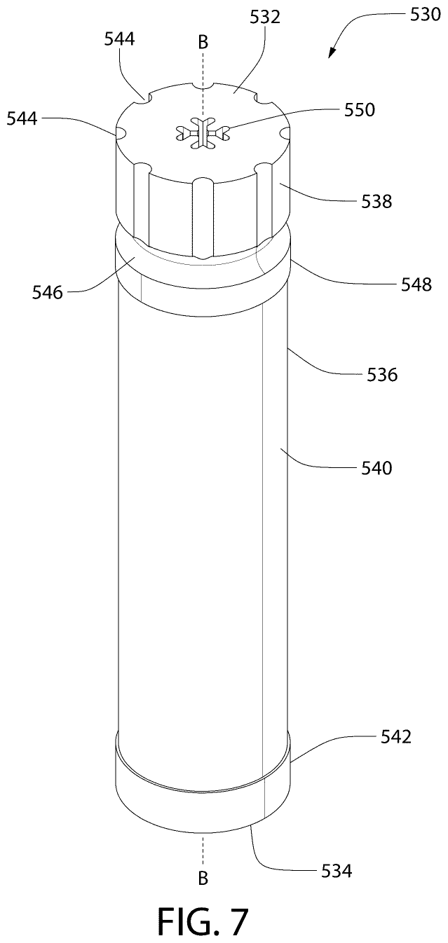

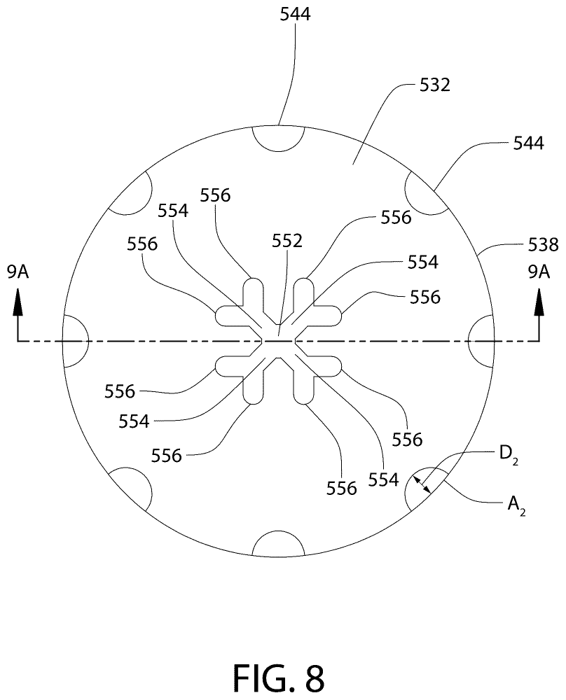

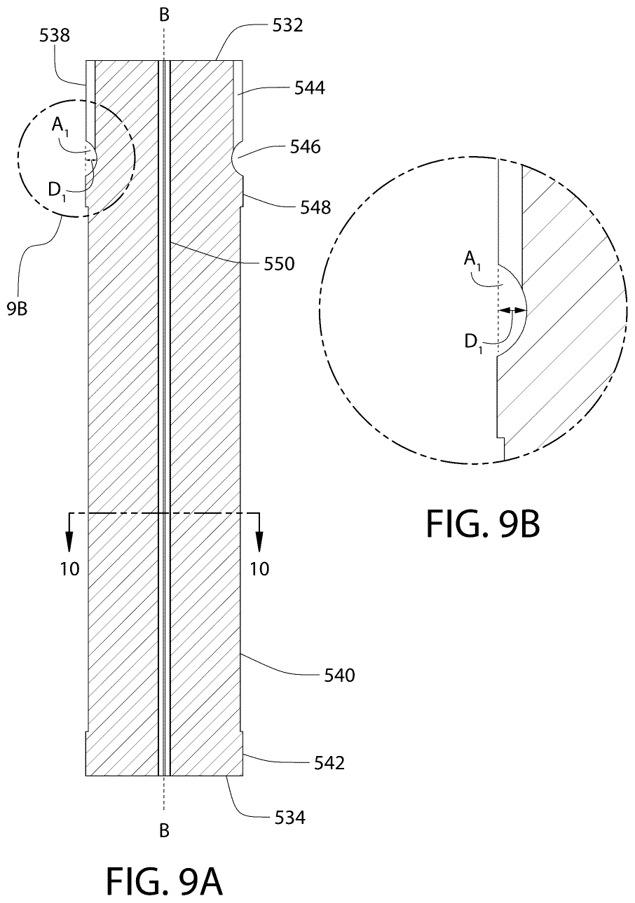

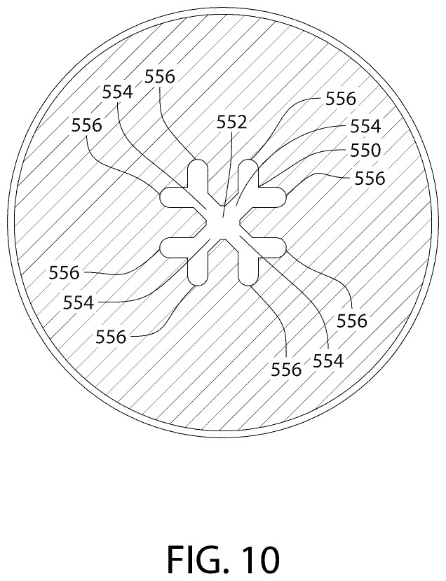

Turning to FIGS. 7-10, a first embodiment of a flow restrictor 530 is illustrated. The flow restrictor 530 extends from a first end 532 to a second end 534 along a longitudinal axis B-B. The flow restrictor 530 further comprises an outer surface 536 extending from the first end 532 to the second end 534. The outer surface 536 comprises an upper portion 538 extending from the first end 532 to a recessed portion 540, the upper portion 538 having a greater diameter than the recessed portion 540. A lower portion 542 is between the recessed portion 540 and the second end 534. The lower portion 542 may have a diameter equal to the diameter of the upper portion 538 or may have a different diameter than the diameter of the upper portion 538. The diameter of the lower portion 542 is greater than the diameter of the recessed portion 540.

The upper and lower portions 538, 542 may be configured to engage the wall 433 of the recess 431 and/or the seat 440. The recessed portion 540 may have a diameter selected to avoid contact with the wall 433 while the upper and lower portions 538, 542 may be selected to provide a fluid-tight seal with the wall 433 and/or the seat 440. The upper portion 538 has a plurality of longitudinal grooves 544 and a circumferential groove 546. The longitudinal grooves 544 extend from the first end 532 to the circumferential groove 546. The longitudinal grooves 544 may be circumferentially spaced about the longitudinal axis B-B and may be either equally or unequally spaced about the longitudinal axis B-B. The longitudinal grooves 544 extend parallel to the longitudinal axis B-B while the circumferential groove 546 extends perpendicular to the longitudinal axis B-B. The circumferential groove 546 is immediately adjacent to the seat 440 and proximate the first end 532.

The circumferential groove 546 may encircle an entirety of the circumference of the flow restrictor 530. Preferably, the circumferential groove 546 is formed into the upper portion 538 and is spaced from both the first end 532 and the recessed portion 540, providing an upper sealing surface 548 formed between the circumferential groove 546 and the recessed portion 540 that is uninterrupted about the circumference of the flow restrictor 530. Thus, the upper sealing surface 548 has no grooves, cuts, or other breaks about the circumference of the flow restrictor 530. This ensures that the upper sealing surface 548 can engage a corresponding surface such as the wall 433 of the recess 431 and achieve a fluid-tight connection.

The circumferential groove 546 allows fluid communication with the first end 532 via the longitudinal grooves 544. The circumferential groove 546 preferably has a first cross-sectional area A₁ and the longitudinal grooves 544 each have a second cross-sectional area A₂. The first cross-sectional area A₁ is greater than the second cross-sectional area A₂. In other implementations, the second cross-sectional area A₂ may be equal to or greater than the first cross-sectional area A₁. The circumferential groove 546 also has a first radial depth D₁ and the longitudinal groove has a second radial depth D₂. The first radial depth D₁ is greater than the second radial depth D₂, but in other implementations the first radial depth D₁ may be equal to or less than the second radial depth D₂.

In some implementations, the circumferential groove 546 and the longitudinal grooves 544 may have a semi-circular cross-section. In other implementations, the circumferential groove 546 and the longitudinal grooves 544 may have a flat bottom and square or angled sides. Other shapes are also contemplated.

When the flow restrictor 530 is installed within the recess 431, the circumferential groove 546 is in fluid communication with the fluid connection path 432, allowing fluid communication between the pressure sensor 130 and the first end 532 of the flow restrictor 530 via the longitudinal grooves 544. Thus, the longitudinal grooves 544 provide fluid communication from the first end 532 to the circumferential groove 546 and the circumferential groove 546 provides fluid communication with the fluid connection path 432. The circumferential groove 546 need not extend around the entire circumference of the flow restrictor 530, but doing so avoids a need to rotationally align the flow restrictor 530 within the recess 431. The number and spacing of the longitudinal grooves 544 may vary and may be equally spaced about the circumference of the flow restrictor 530 or may be unequally spaced as desired. A single longitudinal groove 544 may be used in lieu of a plurality of longitudinal grooves 544 so long as fluid communication is maintained between the first end 532 and the circumferential groove 546.

The flow restrictor 530 further has a restriction path 550 which extends from the first end 532 to the second end 534 along the longitudinal axis B-B. The restriction path 550 may have any desired cross-sectional profile, including round, polygonal, or branched as illustrated. The restriction path 550 has a constant cross-sectional profile along the longitudinal axis B-B but need not have a constant profile in all implementations. The cross-sectional profile may vary, tapering or having non-linear variations along the length of the flow restrictor 530 from the first end 532 to the second end 534.

The restriction path 550 may have a central portion 552 and a plurality of branched portions 554 extending from the central portion 552. The branched portions 554 may further incorporate a plurality of slots 556 extending from the branched portions 554. The number of slots 556 and branched portions 554 may vary, allowing the flow restrictor 530 to have different flow impedances depending on the total cross-sectional area of the restriction path 550. Optionally, the slots 556 may be symmetrical about the branched portions. The slots 556 may have equal width when viewed in cross-section. The restriction path 550 is not in fluid communication with the outer surface 536 except via the first and second ends 532, 534, ensuring that the impedance is solely determined by the restriction path 550.

The branched portions 554 and the slots 556 may be symmetric about the longitudinal axis B-B and may extend from the longitudinal axis B-B toward the outer surface 536 without reaching the outer surface 536. The branched portions 554 and slots 556 may be arranged to minimize the pressure differential across the first end 532, minimizing flow turbulence. The restriction path 550 may be arranged to maximize laminar flow and minimize areas of low flow velocity. In some configurations, the restriction path 550 may be formed by a single passage which may optionally be centered on and intersected by the longitudinal axis B-B. In other configurations, the restriction path 550 may be formed by a plurality of individual passages. These individual passages need not be intersected by the longitudinal axis B-B, and need not be symmetrically arranged about the longitudinal axis B-B.

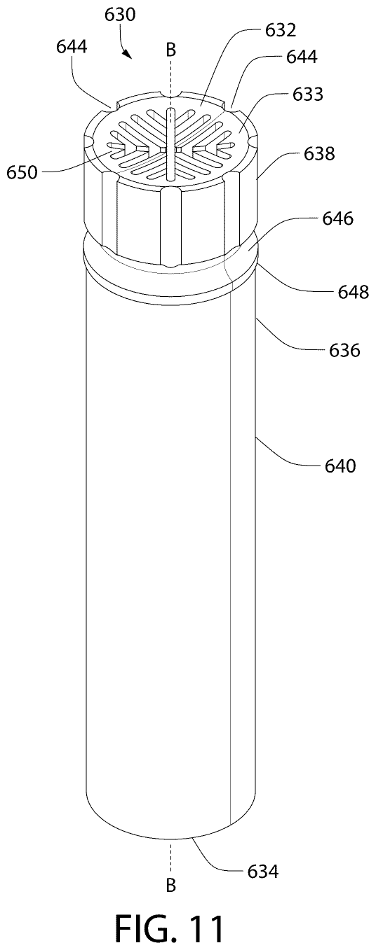

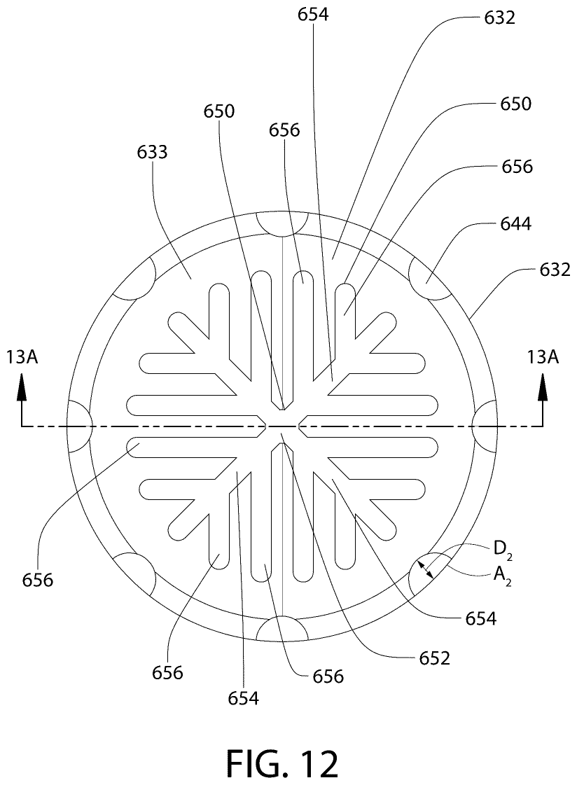

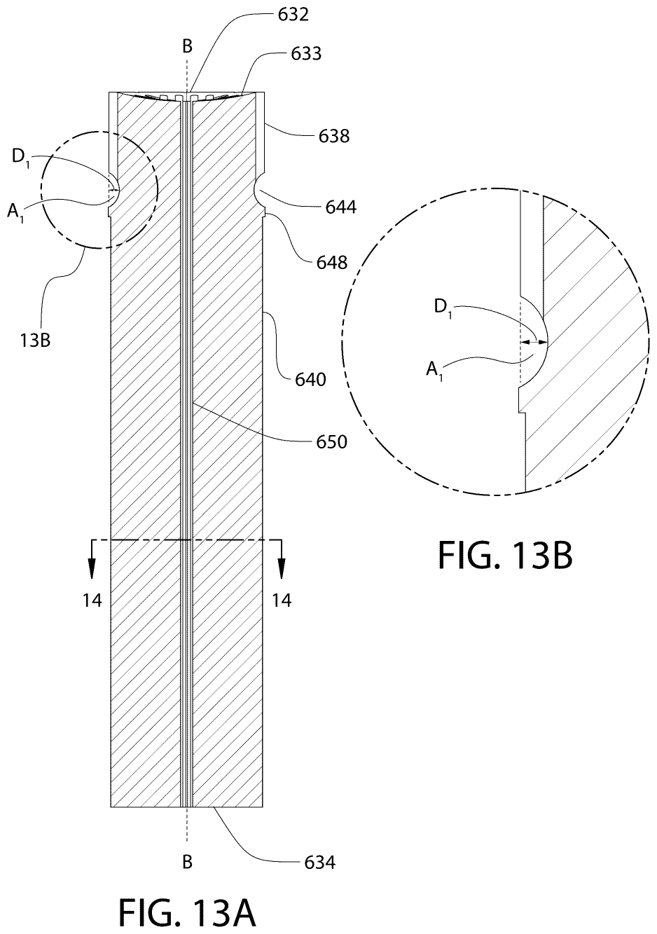

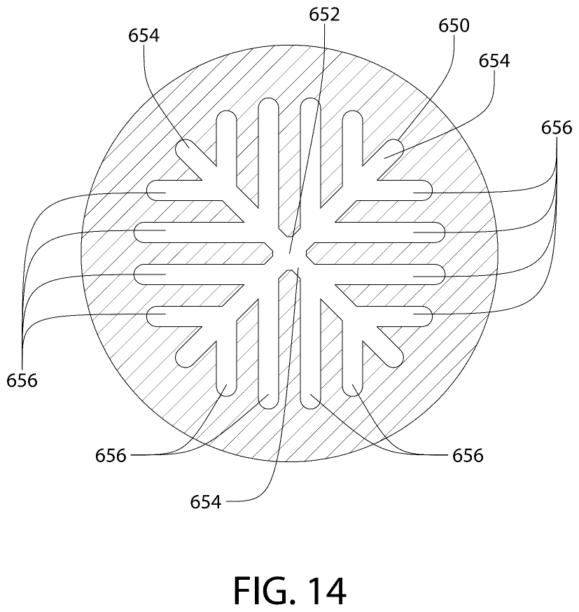

Turning to FIGS. 11-14, another embodiment of a flow restrictor 630 is illustrated. The flow restrictor 630 extends from a first end 632 to a second end 634 along a longitudinal axis B-B. The flow restrictor 630 further comprises an outer surface 636 extending from the first end 632 to the second end 634. The outer surface 636 comprises an upper portion 638 extending from the first end 632 to a recessed portion 640, the upper portion 638 having a greater diameter than the recessed portion 640. The recessed portion 640 extends from the upper portion 638 to the second end 634.

The upper portion 638 may be configured to engage the wall 433 of the recess 431 and/or the seat 440. The recessed portion 640 may have a diameter selected to avoid contact with the wall 433 while the upper portion 638 may be selected to provide a fluid-tight seal with the wall 433 and/or the seat 440. The upper portion 638 has a plurality of longitudinal grooves 644 and a circumferential groove 646. The longitudinal grooves 644 extend from the first end 632 to the circumferential groove 646. The longitudinal grooves 644 may be circumferentially spaced about the longitudinal axis B-B and may be either equally or unequally spaced about the longitudinal axis B-B. The longitudinal grooves 644 extend parallel to the longitudinal axis B-B while the circumferential groove 646 extends perpendicular to the longitudinal axis B-B. The circumferential groove 646 is immediately adjacent to the seat 440 and proximate the first end 632.

The circumferential groove 646 may encircle an entirety of the circumference of the flow restrictor 630. Preferably, the circumferential groove 646 is formed into the upper portion 638 and is spaced from both the first end 632 and the recessed portion 640, providing an upper sealing surface 648 formed between the circumferential groove 646 and the recessed portion 640 that is uninterrupted about the circumference of the flow restrictor 630. Thus, the upper sealing surface 648 has no grooves, cuts, or other breaks about the circumference of the flow restrictor 630. This ensures that the upper sealing surface 648 can engage a corresponding surface such as the wall 433 of the recess 431 and achieve a fluid-tight connection.

The circumferential groove 646 allows fluid communication with the first end 632 via the longitudinal grooves 644. The circumferential groove 646 preferably has a first cross-sectional area A₁ and the longitudinal grooves 644 each have a second cross-sectional area A₂. The first cross-sectional area A₁ is greater than the second cross-sectional area A₂. In other implementations, the second cross-sectional area A₂ may be equal to or greater than the first cross-sectional area A₁. The circumferential groove 646 also has a first radial depth D₁ and the longitudinal groove has a second radial depth D₂. The first radial depth D₁ is greater than the second radial depth D₂, but in other implementations the first radial depth D₁ may be equal to or less than the second radial depth D₂.

In some implementations, the circumferential groove 646 and the longitudinal grooves 644 may have a semi-circular cross-section. In other implementations, the circumferential groove 646 and the longitudinal grooves 644 may have a flat bottom and square or angled sides. Other shapes are also contemplated.

When the flow restrictor 630 is installed within the recess 431, the circumferential groove 646 is in fluid communication with the fluid connection path 432, allowing fluid communication between the pressure sensor 130 and the first end 632 of the flow restrictor 630 via the longitudinal grooves 644. Thus, the longitudinal grooves 644 provide fluid communication from the first end 632 to the circumferential groove 646 and the circumferential groove 646 provides fluid communication with the fluid connection path 432. The circumferential groove 646 need not extend around the entire circumference of the flow restrictor 630, but doing so avoids a need to rotationally align the flow restrictor 630 within the recess 431. The number and spacing of the longitudinal grooves 644 may vary and may be equally spaced about the circumference of the flow restrictor 630 or may be unequally spaced as desired. A single longitudinal groove 644 may be used in lieu of a plurality of longitudinal grooves 644 so long as fluid communication is maintained between the first end 632 and the circumferential groove 646.

The flow restrictor 630 further has a restriction path 650 which extends from the first end 632 to the second end 634 along the longitudinal axis B-B. The restriction path 650 may have any desired cross-sectional profile, including round, polygonal, or branched as illustrated. The restriction path 650 has a constant cross-sectional profile along the longitudinal axis B-B but need not have a constant profile in all implementations. The cross-sectional profile may vary, tapering or having non-linear variations along the length of the flow restrictor 630 from the first end 632 to the second end 634. The first end 632 may incorporate a concave surface 633 or the first end 632 may be planar as desired.

The restriction path 650 may have a central portion 652 and a plurality of branched portions 654 extending from the central portion 652. The branched portions 654 may further incorporate a plurality of slots 656 extending from the branched portions 654. The number of slots 656 and branched portions 654 may vary, allowing the flow restrictor 630 to have different flow impedances depending on the total cross-sectional area of the restriction path 650. In the flow restrictor 630, the restriction path 650 has four branched portions 654, each branched portion 654 having two pairs of slots 656. The slots 656 extend parallel to other slots 656 of other branched portions 654 and are symmetrical about their respective branched portions 654.

Spacing between the slots 656 is substantially equal, and optionally the branched portion may extend beyond the slots 656. The slots 656 may have equal width when viewed in cross-section. The slots 656 and branched portions 654 may have the same width as illustrated or may have a different width as desired. It is contemplated that the branched portions 654 may have a greater width than the slots 656 or the branched portions 654 may have the same width as the slots 656. The restriction path 650 is not in fluid communication with the outer surface 636 except via the first and second ends 632, 634, ensuring that the impedance is solely determined by the restriction path 650.

The branched portions 654 and the slots 656 may be rotationally symmetric about the longitudinal axis B-B and may extend from the longitudinal axis B-B toward the outer surface 636 without reaching the outer surface 636. The branched portions 654 and slots 656 may be arranged to minimize the pressure differential across the first end 632, minimizing flow turbulence. The restriction path 650 may be arranged to maximize laminar flow and minimize areas of low flow velocity. In some configurations, the restriction path 650 may be formed by a single passage which may optionally be centered on and intersected by the longitudinal axis B-B. In other configurations, the restriction path 650 may be formed by a plurality of individual passages. These individual passages need not be intersected by the longitudinal axis B-B, and need not be symmetrically arranged about the longitudinal axis B-B.

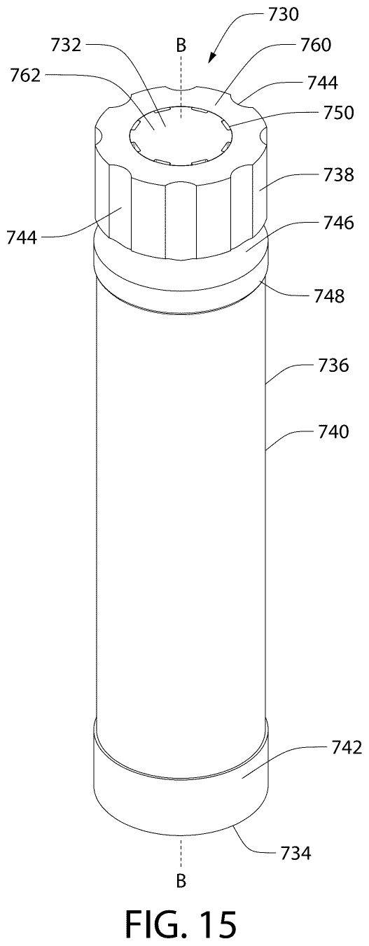

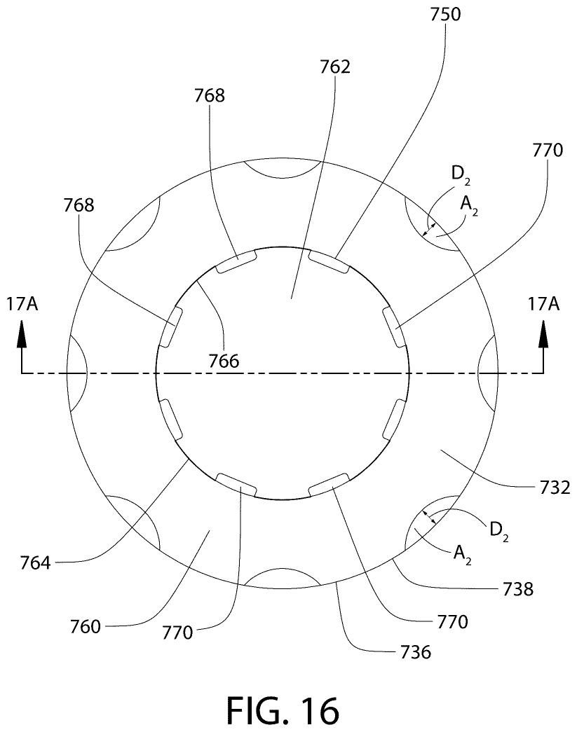

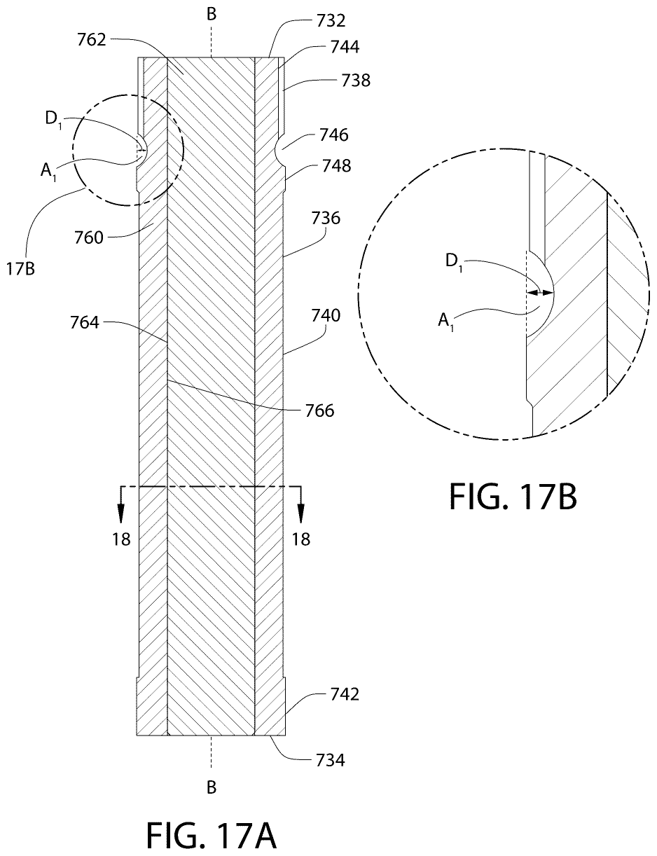

FIGS. 15-18 illustrate yet another embodiment of a flow restrictor 730. The flow restrictor 730 extends from a first end 732 to a second end 734 along a longitudinal axis B-B. The flow restrictor 730 further comprises an outer surface 736 extending from the first end 732 to the second end 734. The outer surface 736 comprises an upper portion 738 extending from the first end 732 to a recessed portion 740, the upper portion 738 having a greater diameter than the recessed portion 740. A lower portion 742 is between the recessed portion 740 and the second end 734. The lower portion 742 may have a diameter equal to the diameter of the upper portion 738 or may have a different diameter than the diameter of the upper portion 738. The diameter of the lower portion 742 is greater than the diameter of the recessed portion 740.

The upper and lower portions 738, 742 may be configured to engage the wall 433 of the recess 431 and/or the seat 440. The recessed portion 740 may have a diameter selected to avoid contact with the wall 433 while the upper and lower portions 738, 742 may be selected to provide a fluid-tight seal with the wall 433 and/or the seat 440. The upper portion 738 has a plurality of longitudinal grooves 744 and a circumferential groove 746. The longitudinal grooves 744 extend from the first end 732 to the circumferential groove 746. The longitudinal grooves 744 may be circumferentially spaced about the longitudinal axis B-B and may be either equally or unequally spaced about the longitudinal axis B-B. The longitudinal grooves 744 extend parallel to the longitudinal axis B-B while the circumferential groove 746 extends perpendicular to the longitudinal axis B-B. The circumferential groove 746 is immediately adjacent to the seat 440 and proximate the first end 732.

The circumferential groove 746 may encircle an entirety of the circumference of the flow restrictor 730. Preferably, the circumferential groove 746 is formed into the upper portion 738 and is spaced from both the first end 732 and the recessed portion 740, providing an upper sealing surface 748 formed between the circumferential groove 746 and the recessed portion 740 that is uninterrupted about the circumference of the flow restrictor 730. Thus, the upper sealing surface 748 has no grooves, cuts, or other breaks about the circumference of the flow restrictor 730. This ensures that the upper sealing surface 748 can engage a corresponding surface such as the wall 433 of the recess 431 and achieve a fluid-tight connection.

The circumferential groove 746 allows fluid communication with the first end 732 via the longitudinal grooves 744. The circumferential groove 746 preferably has a first cross-sectional area A₁ and the longitudinal grooves 744 each have a second cross-sectional area A₂. The first cross-sectional area A₁ is greater than the second cross-sectional area A₂. In other implementations, the second cross-sectional area A₂ may be equal to or greater than the first cross-sectional area A₁. The circumferential groove 746 also has a first radial depth D₁ and the longitudinal groove has a second radial depth D₂. The first radial depth D₁ is greater than the second radial depth D₂, but in other implementations the first radial depth D₁ may be equal to or less than the second radial depth D₂.

In some implementations, the circumferential groove 746 and the longitudinal grooves 744 may have a semi-circular cross-section. In other implementations, the circumferential groove 746 and the longitudinal grooves 744 may have a flat bottom and square or angled sides. Other shapes are also contemplated.

When the flow restrictor 730 is installed within the recess 431, the circumferential groove 746 is in fluid communication with the fluid connection path 432, allowing fluid communication between the pressure sensor 130 and the first end 732 of the flow restrictor 730 via the longitudinal grooves 744. Thus, the longitudinal grooves 744 provide fluid communication from the first end 732 to the circumferential groove 746 and the circumferential groove 746 provides fluid communication with the fluid connection path 432. The circumferential groove 746 need not extend around the entire circumference of the flow restrictor 730, but doing so avoids a need to rotationally align the flow restrictor 730 within the recess 431. The number and spacing of the longitudinal grooves 744 may vary and may be equally spaced about the circumference of the flow restrictor 730 or may be unequally spaced as desired. A single longitudinal groove 744 may be used in lieu of a plurality of longitudinal grooves 744 so long as fluid communication is maintained between the first end 732 and the circumferential groove 746.

The flow restrictor 730 further has a restriction path 750 which extends from the first end 732 to the second end 734 along the longitudinal axis B-B. The restriction path 750 may have any desired cross-sectional profile, including round, polygonal, or branched as illustrated. The restriction path 750 has a constant cross-sectional profile along the longitudinal axis B-B but need not have a constant profile in all implementations. The cross-sectional profile may vary, tapering or having non-linear variations along the length of the flow restrictor 730 from the first end 732 to the second end 734. The first end 732 may incorporate a concave surface or the first end 732 may be planar as desired.

The flow restrictor 730 may be constructed as an outer ring 760 and an inner ring 762. The outer ring 760 may be generally cylindrical and have a bore 764 which receives the inner ring 762. An outer surface 766 of the inner ring 762 may be a close fit with the bore 764. This may be achieved as a press fit, shrink fit, or the like. Thus, no fluid can pass between the inner ring 762 and the outer ring 760 except via the restriction path 750. Optionally, a plurality of inner rings 762 may be utilized, with some of the inner rings 762 having a bore 764 and one of the inner rings 762 lacking a bore 764. Thus, one inner ring 762 is a solid cylinder while other ones of the inner rings 762 may be hollow cylinders having a tubular configuration similar to the outer ring 760.

The inner ring 762 may have a plurality of grooves 768 formed into the outer surface 766. The grooves 768 form a plurality of passages 770 when the inner ring 762 is nested within the outer ring 760. The passages 770 collectively form the restriction path 750, with the number of passages 770 and the width and depth of the grooves 768 altering the flow impedance of the restriction path 750.

The grooves 768 may have parallel, tapered, or arcuate walls and a flat or arcuate floor. The grooves 768 may be any known shape and may be equally spaced about the inner ring 762 or unequally spaced as desired. Increasing the area of the grooves 768 decreases the flow impedance of the restriction path 750. Increasing the number of grooves 768 also decreases the flow impedance of the restriction path 750. As noted above, additional inner rings 762 may be utilized to form additional passages 770.

Furthermore, it is contemplated that the grooves 768 may be formed into the bore 764 instead of the outer surface 766, or grooves 768 may be formed into both the bore 764 and the outer surface 766. The grooves 768 need not be equal in size, and may vary in shape, area, depth, or width on the same inner ring 762 or outer ring 760. Additionally, the grooves 768 may vary between different ones of the inner rings 762 where a plurality of inner rings 762 are utilized. The grooves 768 and the resulting passages 770 may be rotationally symmetric about the longitudinal axis B-B.

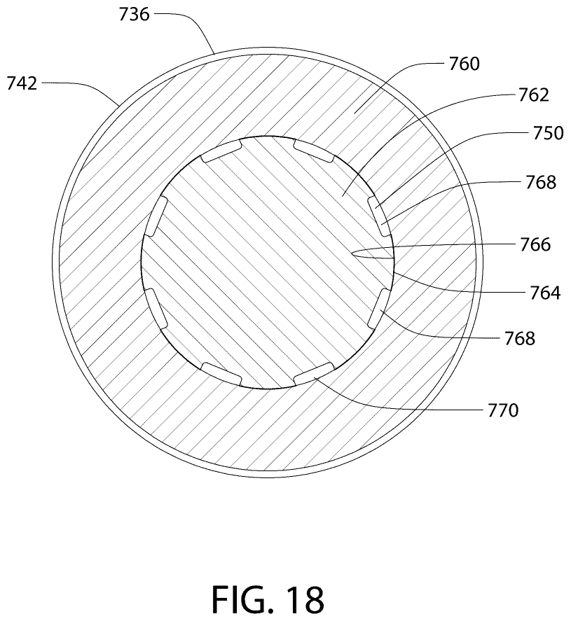

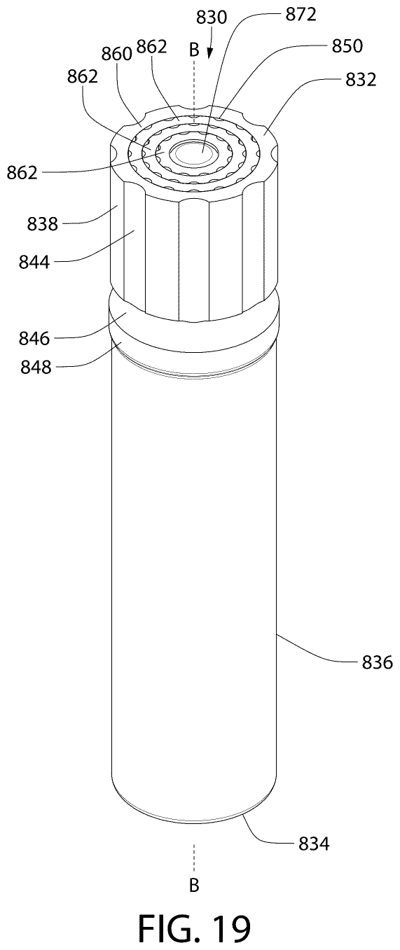

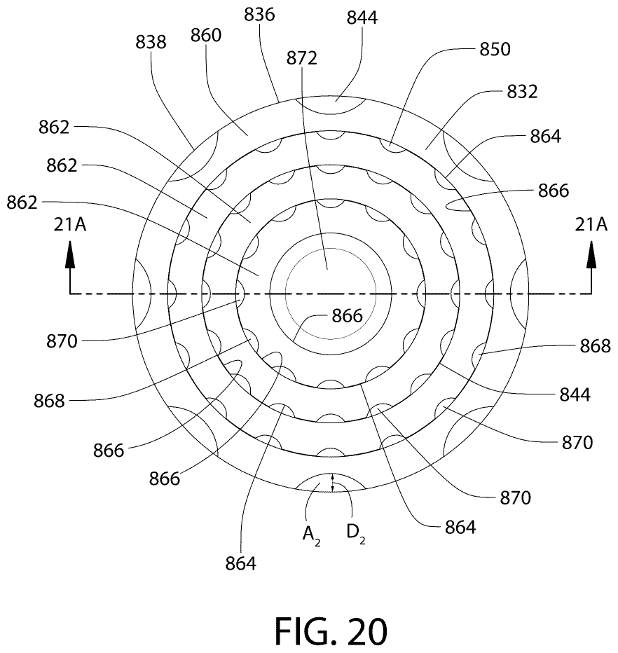

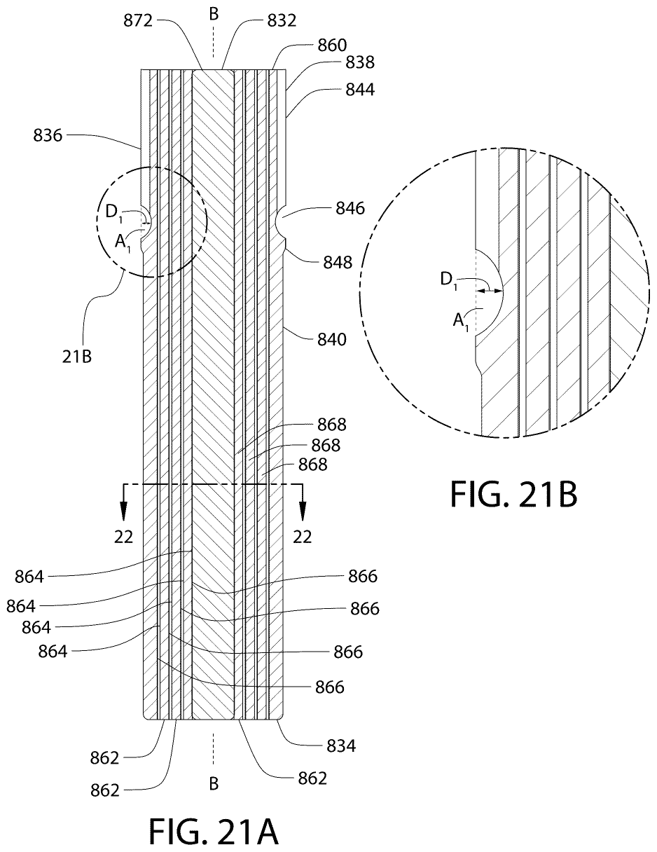

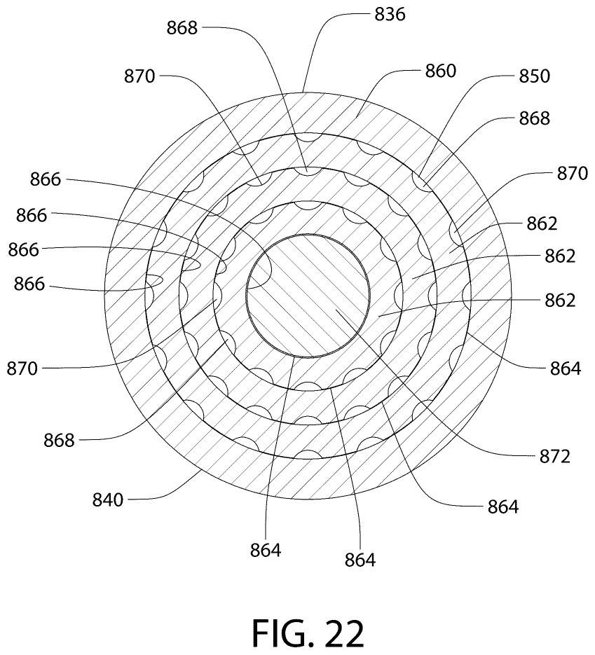

FIGS. 18-22 illustrate a further embodiment of a flow restrictor 830. The flow restrictor 830 extends from a first end 832 to a second end 834 along a longitudinal axis B-B. The flow restrictor 830 further comprises an outer surface 836 extending from the first end 832 to the second end 834. The outer surface 836 comprises an upper portion 838 extending from the first end 832 to a recessed portion 840, the upper portion 838 having a greater diameter than the recessed portion 840. The recessed portion 840 extends from the upper portion 838 to the second end 834.

The upper portion 838 may be configured to engage the wall 433 of the recess 431 and/or the seat 440. The recessed portion 840 may have a diameter selected to avoid contact with the wall 433 while the upper portion 838 may be selected to provide a fluid-tight seal with the wall 433 and/or the seat 440. The upper portion 838 has a plurality of longitudinal grooves 844 and a circumferential groove 846. The longitudinal grooves 844 extend from the first end 832 to the circumferential groove 846. The longitudinal grooves 844 may be circumferentially spaced about the longitudinal axis B-B and may be either equally or unequally spaced about the longitudinal axis B-B. The longitudinal grooves 844 extend parallel to the longitudinal axis B-B while the circumferential groove 846 extends perpendicular to the longitudinal axis B-B. The circumferential groove 846 is immediately adjacent to the seat 440 and proximate the first end 832.

The circumferential groove 846 may encircle an entirety of the circumference of the flow restrictor 830. Preferably, the circumferential groove 846 is formed into the upper portion 838 and is spaced from both the first end 832 and the recessed portion 840, providing an upper sealing surface 848 formed between the circumferential groove 846 and the recessed portion 840 that is uninterrupted about the circumference of the flow restrictor 830. Thus, the upper sealing surface 848 has no grooves, cuts, or other breaks about the circumference of the flow restrictor 830. This ensures that the upper sealing surface 848 can engage a corresponding surface such as the wall 433 of the recess 431 and achieve a fluid-tight connection.

The circumferential groove 846 allows fluid communication with the first end 832 via the longitudinal grooves 844. The circumferential groove 846 preferably has a first cross-sectional area A₁ and the longitudinal grooves 844 each have a second cross-sectional area A₂. The first cross-sectional area A₁ is greater than the second cross-sectional area A₂. In other implementations, the second cross-sectional area A₂ may be equal to or greater than the first cross-sectional area A₁. The circumferential groove 846 also has a first radial depth D₁ and the longitudinal groove has a second radial depth D₂. The first radial depth D₁ is greater than the second radial depth D₂, but in other implementations the first radial depth D₁ may be equal to or less than the second radial depth D₂.

In some implementations, the circumferential groove 846 and the longitudinal grooves 844 may have a semi-circular cross-section. In other implementations, the circumferential groove 846 and the longitudinal grooves 844 may have a flat bottom and square or angled sides. Other shapes are also contemplated.

When the flow restrictor 830 is installed within the recess 431, the circumferential groove 846 is in fluid communication with the fluid connection path 432, allowing fluid communication between the pressure sensor 130 and the first end 832 of the flow restrictor 830 via the longitudinal grooves 844. Thus, the longitudinal grooves 844 provide fluid communication from the first end 832 to the circumferential groove 846 and the circumferential groove 846 provides fluid communication with the fluid connection path 432. The circumferential groove 846 need not extend around the entire circumference of the flow restrictor 830, but doing so avoids a need to rotationally align the flow restrictor 830 within the recess 431. The number and spacing of the longitudinal grooves 844 may vary and may be equally spaced about the circumference of the flow restrictor 830 or may be unequally spaced as desired. A single longitudinal groove 844 may be used in lieu of a plurality of longitudinal grooves 844 so long as fluid communication is maintained between the first end 832 and the circumferential groove 846.

The flow restrictor 830 further has a restriction path 850 which extends from the first end 832 to the second end 834 along the longitudinal axis B-B. The restriction path 850 may have any desired cross-sectional profile, including round, polygonal, or branched as illustrated. The restriction path 850 has a constant cross-sectional profile along the longitudinal axis B-B but need not have a constant profile in all implementations. The cross-sectional profile may vary, tapering or having non-linear variations along the length of the flow restrictor 830 from the first end 832 to the second end 834. The first end 832 may incorporate a concave surface or the first end 832 may be planar as desired.

The flow restrictor 830 may be constructed as an outer ring 860 and a plurality of inner rings 862. The plurality of inner rings 862 may include a center ring 872. The outer ring 860 may be generally cylindrical and have a bore 864 which receives an outermost one of the plurality of inner rings 862. An outer surface 866 of the outermost one of the plurality of inner rings 862 may be a close fit with the bore 864 of the outer ring 860. This may be achieved as a press fit, shrink fit, or the like. Thus, no fluid can pass between the outermost one of the plurality of inner rings 862 and the outer ring 860 except via the restriction path 850.

The outermost one of the plurality of inner rings 862 may be referred to as a first inner ring 862. The first inner ring 862 further incorporates a bore 864 which receives a second inner ring 862. The second inner ring 862 also has a bore 864 which receives a third inner ring 862. The third inner ring 862 has a bore 864 which receives the center ring 872. Optionally, each of the bores 864 and the respective outer surfaces 866 of the plurality of inner rings 862 may be a close fit as discussed above. The bores 864 and outer surfaces 866 may be a press fit, shrink fit, or any other known process to ensure that no fluid can pass between the bores 864 and outer surfaces 866 except via the restriction path 850.

Each of the inner rings 862 is preferably cylindrical, and all but the center ring 872 may be hollow cylinders. The center ring 872 may be a solid cylinder as desired. It is contemplated that any number of inner rings 862 may be utilized as desired. The inner rings 862 may have a bore 864 excepting the center ring 872 which may lack a bore 864. Thus, the plurality of inner rings 862 are solid cylinders having a tubular configuration similar to the outer ring 860 excepting the center ring 872 which may be a solid cylinder.

Some or all of the plurality of inner rings 862 may have a plurality of grooves 868 formed into their respective outer surfaces 866. The grooves 868 form a plurality of passages 870 when the plurality of inner rings 862 are nested within the outer ring 860. The passages 870 collectively form the restriction path 850, with the number of passages 870 and the width and depth of the grooves 868 altering the flow impedance of the restriction path 850.

The grooves 868 of the flow restrictor 830 are arcuate, but in other implementations the grooves 868 may have parallel, tapered, or arcuate walls and a flat or arcuate floor. The grooves 868 may be any known shape and may be equally spaced about the inner rings 862 or unequally spaced as desired. The grooves 868 may also be different on different ones of the inner rings 862. Increasing the area of the grooves 868 decreases the flow impedance of the restriction path 850. Increasing the number of grooves 868 also decreases the flow impedance of the restriction path 850.

As illustrated, the center ring 872 has no grooves 868, but in other implementations the center ring 872 may incorporate grooves 868 as desired. The inner rings 862 may be arranged with grooves 868 from different ones of the inner rings 862 aligned or may be arranged such that the inner rings 862 are in a random orientation. The number and spacing of the grooves 868 as well as the alignment of the inner rings 862 may be arranged to optimize the pressure differential at the first end 832 of the flow restrictor. For example, it may be desirable to minimize the pressure differential at the first end 832 so as to minimize turbulence of the fluid flow as it enters the restriction path 850.

Furthermore, it is contemplated that the grooves 868 may be formed into the bores 864 instead of the outer surfaces 866, or grooves 868 may be formed into both the bores 864 and the outer surfaces 866. The grooves 868 need not be equal in size, and may vary in shape, area, depth, or width on the same inner ring 862 or outer ring 860. Additionally, the grooves 868 may vary between different ones of the inner rings 862 where a plurality of inner rings 862 are utilized. The grooves 868 and the resulting passages 870 may be rotationally symmetric about the longitudinal axis B-B if desired.

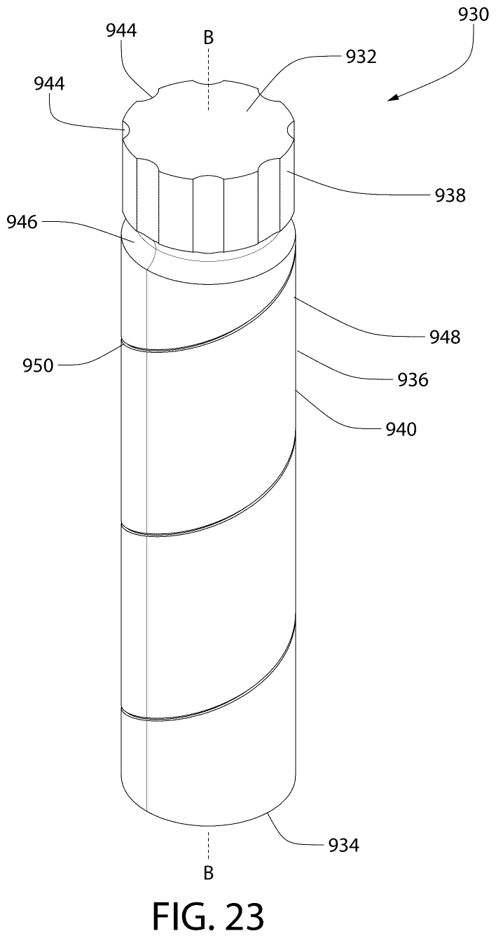

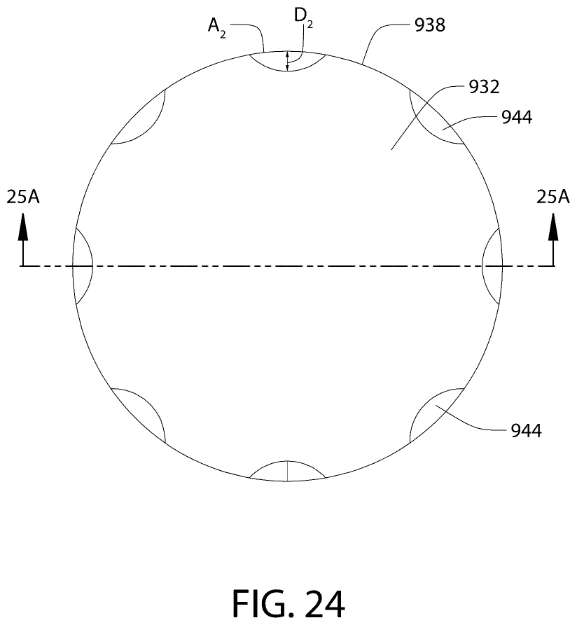

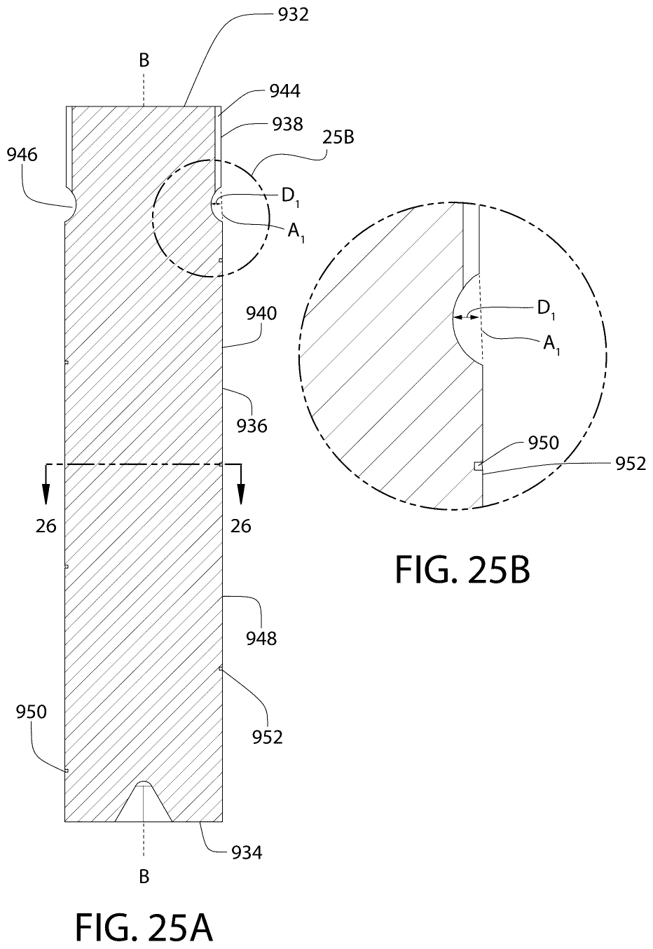

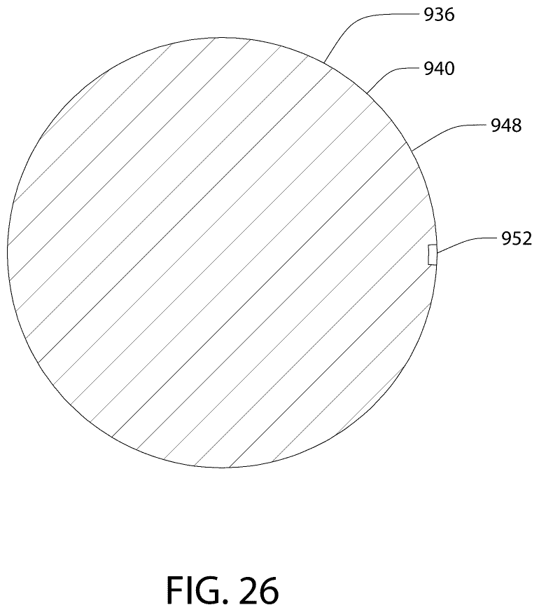

Turning to FIGS. 23-26, a fifth embodiment of a flow restrictor 930 is illustrated. The flow restrictor 930 extends from a first end 932 to a second end 934 along a longitudinal axis B-B. The flow restrictor 930 further comprises an outer surface 936 extending from the first end 932 to the second end 934. The outer surface 936 comprises an upper portion 938 extending from the first end 932 to a main body portion 940, the upper portion 938 preferably having an equal diameter to the main body portion 940. In other implementations, the upper portion 938 may have a lesser diameter than the main body portion 940.

The upper and main body portions 938, 940 may be configured to engage the wall 433 of the recess 431 and/or the seat 440. The upper portion 938 and the main body portion 940 may have a diameter selected to engage the wall 433. The diameter may be selected to provide a fluid-tight seal with the wall 433 and/or the seat 440. As noted above, the diameters of the upper portion 938 and the main body portion 940 may differ. If they differ, the main body portion 940 is preferably selected to provide a fluid-tight seal with the wall 433 and/or the seat 440. The upper portion 938 has a plurality of longitudinal grooves 944 and a circumferential groove 946. The longitudinal grooves 944 extend from the first end 932 to the circumferential groove 946. The longitudinal grooves 944 may be circumferentially spaced about the longitudinal axis B-B and may be either equally or unequally spaced about the longitudinal axis B-B. The longitudinal grooves 944 extend parallel to the longitudinal axis B-B while the circumferential groove 946 extends perpendicular to the longitudinal axis B-B. The circumferential groove 946 is immediately adjacent to the seat 440 and proximate the first end 932.

The circumferential groove 946 may encircle an entirety of the circumference of the flow restrictor 930. Preferably, the circumferential groove 946 is formed into the upper portion 938 and defines the transition between the upper portion 938 and the main body portion 940. The main body portion 940 forms a sealing surface 948 that is uninterrupted about the circumference of the flow restrictor 930, except as noted below. The sealing surface 948 is configured to engage a corresponding surface such as the wall 433 of the recess 431 and achieve a fluid-tight connection except as noted below.

The circumferential groove 946 allows fluid communication with the first end 932 via the longitudinal grooves 944. The circumferential groove 946 preferably has a first cross-sectional area A₁ and the longitudinal grooves 944 each have a second cross-sectional area A₂. The first cross-sectional area A₁ is greater than the second cross-sectional area A₂. In other implementations, the second cross-sectional area A₂ may be equal to or greater than the first cross-sectional area A₁. The circumferential groove 946 also has a first radial depth D₁ and the longitudinal groove has a second radial depth D₂. The first radial depth D₁ is greater than the second radial depth D₂, but in other implementations the first radial depth D₁ may be equal to or less than the second radial depth D₂.

In some implementations, the circumferential groove 946 and the longitudinal grooves 944 may have a semi-circular cross-section. In other implementations, the circumferential groove 946 and the longitudinal grooves 944 may have a flat bottom and square or angled sides. Other shapes are also contemplated.

When the flow restrictor 930 is installed within the recess 431, the circumferential groove 946 is in fluid communication with the fluid connection path 432, allowing fluid communication between the pressure sensor 130 and the first end 932 of the flow restrictor 930 via the longitudinal grooves 944. Thus, the longitudinal grooves 944 provide fluid communication from the first end 932 to the circumferential groove 946 and the circumferential groove 946 provides fluid communication with the fluid connection path 432. The circumferential groove 946 need not extend around the entire circumference of the flow restrictor 930, but doing so avoids a need to rotationally align the flow restrictor 930 within the recess 431. The number and spacing of the longitudinal grooves 944 may vary and may be equally spaced about the circumference of the flow restrictor 930 or may be unequally spaced as desired. A single longitudinal groove 944 may be used in lieu of a plurality of longitudinal grooves 944 so long as fluid communication is maintained between the first end 932 and the circumferential groove 946.

The flow restrictor 930 further has a restriction path 950 which extends from the first end 932 to the second end 934 along the longitudinal axis B-B. The restriction path 950 is formed of the longitudinal grooves 944, the circumferential groove 946, and a passage 952. The passage 952 may have any desired cross-sectional profile, including round, polygonal, or rectangular as illustrated. The passage 952 extends from the circumferential groove 946 to the second end 934. The passage 952 is enclosed by the engagement of the main body portion 940 with the wall 433 of the recess 431. Optionally, the cross-section of the passage 952 of the restriction path 950 may have any desired depth or width to achieve the desired flow restriction.

The passage 952 extends from the circumferential groove 946 along a helical path, but in other implementations the passage 952 may extend straight from the circumferential groove 946 to the second end 934 or may have a path which takes a zig-zag or other path as desired. In some implementations, a plurality of passages 952 may be used. The passage 952 has a constant cross-sectional profile along the longitudinal axis B-B but need not have a constant profile in all implementations. The cross-sectional profile may vary, tapering or having non-linear variations along the length of the flow restrictor 930 from the circumferential groove 946 to the second end 934. Preferably, the cross-sectional area and the length of the passage are selected to achieve laminar flow. Above certain ratios of area to length (greater area per length), the flow becomes turbulent and is no longer laminar, so these ratios are to be avoided.

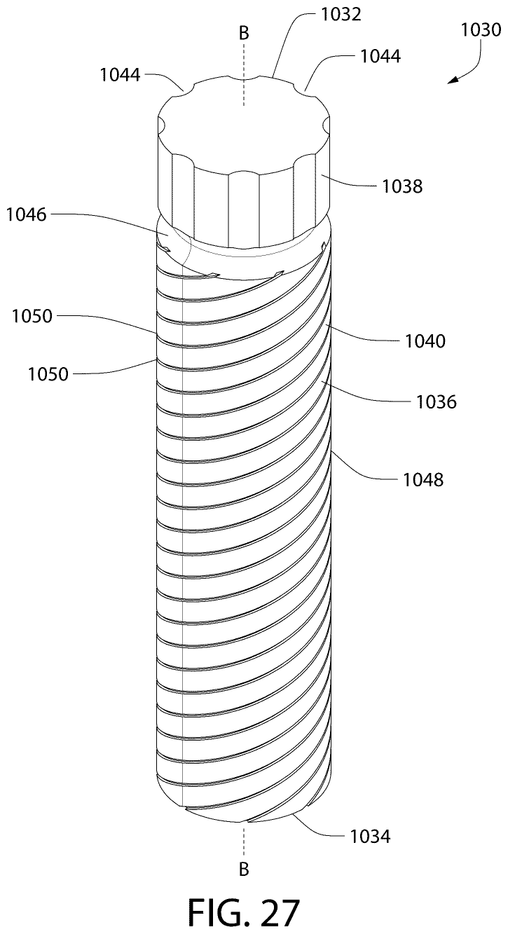

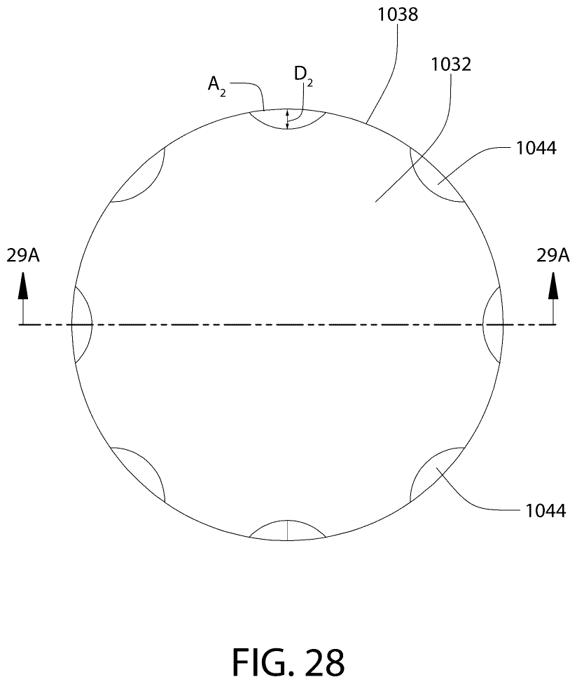

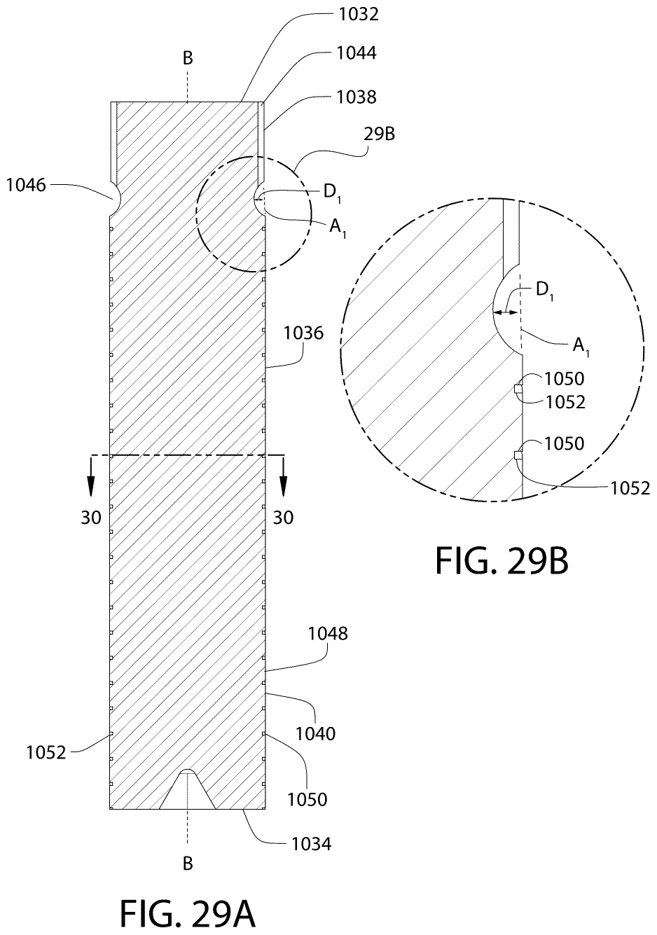

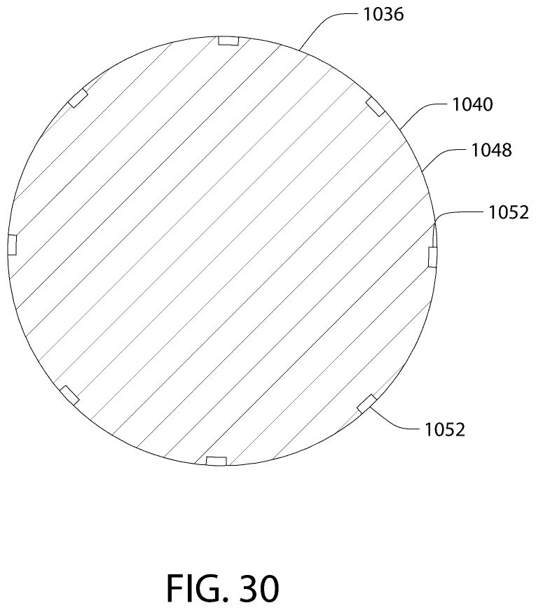

Turning to FIGS. 27-30, a sixth embodiment of a flow restrictor 1030 is illustrated. The flow restrictor 1030 extends from a first end 1032 to a second end 1034 along a longitudinal axis B-B. The flow restrictor 1030 further comprises an outer surface 1036 extending from the first end 1032 to the second end 1034. The outer surface 1036 comprises an upper portion 1038 extending from the first end 1032 to a main body portion 1040, the upper portion 1038 preferably having an equal diameter to the main body portion 1040. In other implementations, the upper portion 1038 may have a lesser diameter than the main body portion 1040.

The upper and main body portions 1038, 1040 may be configured to engage the wall 433 of the recess 431 and/or the seat 440. The upper portion 1038 and the main body portion 1040 may have a diameter selected to engage the wall 433. The diameter may be selected to provide a fluid-tight seal with the wall 433 and/or the seat 440. As noted above, the diameters of the upper portion 1038 and the main body portion 1040 may differ. If they differ, the main body portion 1040 is preferably selected to provide a fluid-tight seal with the wall 433 and/or the seat 440. The upper portion 1038 has a plurality of longitudinal grooves 1044 and a circumferential groove 1046. The longitudinal grooves 1044 extend from the first end 1032 to the circumferential groove 1046. The longitudinal grooves 1044 may be circumferentially spaced about the longitudinal axis B-B and may be either equally or unequally spaced about the longitudinal axis B-B. The longitudinal grooves 1044 extend parallel to the longitudinal axis B-B while the circumferential groove 1046 extends perpendicular to the longitudinal axis B-B. The circumferential groove 1046 is immediately adjacent to the seat 440 and proximate the first end 1032.

The circumferential groove 1046 may encircle an entirety of the circumference of the flow restrictor 1030. Preferably, the circumferential groove 1046 is formed into the upper portion 1038 and defines the transition between the upper portion 1038 and the main body portion 1040. The main body portion 1040 forms a sealing surface 1048 that is uninterrupted about the circumference of the flow restrictor 1030, except as noted below. The sealing surface 1048 is configured to engage a corresponding surface such as the wall 433 of the recess 431 and achieve a fluid-tight connection except as noted below.

The circumferential groove 1046 allows fluid communication with the first end 1032 via the longitudinal grooves 1044. The circumferential groove 1046 preferably has a first cross-sectional area A₁ and the longitudinal grooves 1044 each have a second cross-sectional area A₂. The first cross-sectional area A₁ is greater than the second cross-sectional area A₂. In other implementations, the second cross-sectional area A₂ may be equal to or greater than the first cross-sectional area A₁. The circumferential groove 1046 also has a first radial depth D₁ and the longitudinal groove has a second radial depth D₂. The first radial depth D₁ is greater than the second radial depth D₂, but in other implementations the first radial depth D₁ may be equal to or less than the second radial depth D₂.

In some implementations, the circumferential groove 1046 and the longitudinal grooves 1044 may have a semi-circular cross-section. In other implementations, the circumferential groove 1046 and the longitudinal grooves 1044 may have a flat bottom and square or angled sides. Other shapes are also contemplated.

When the flow restrictor 1030 is installed within the recess 431, the circumferential groove 1046 is in fluid communication with the fluid connection path 432, allowing fluid communication between the pressure sensor 130 and the first end 1032 of the flow restrictor 1030 via the longitudinal grooves 1044. Thus, the longitudinal grooves 1044 provide fluid communication from the first end 1032 to the circumferential groove 1046 and the circumferential groove 1046 provides fluid communication with the fluid connection path 432. The circumferential groove 1046 need not extend around the entire circumference of the flow restrictor 1030, but doing so avoids a need to rotationally align the flow restrictor 1030 within the recess 431. The number and spacing of the longitudinal grooves 1044 may vary and may be equally spaced about the circumference of the flow restrictor 1030 or may be unequally spaced as desired. A single longitudinal groove 1044 may be used in lieu of a plurality of longitudinal grooves 1044 so long as fluid communication is maintained between the first end 1032 and the circumferential groove 1046.

The flow restrictor 1030 further has a restriction path 1050 which extends from the first end 1032 to the second end 1034 along the longitudinal axis B-B. The restriction path 1050 is formed of the longitudinal grooves 1044, the circumferential groove 1046, and a plurality of passages 1052. The passages 1052 may have any desired cross-sectional profile, including round, polygonal, or rectangular as illustrated. The passages 1052 extend from the circumferential groove 1046 to the second end 1034. The passages 1052 are enclosed by the engagement of the main body portion 1040 with the wall 433 of the recess 431. Optionally, the cross-section of the passages 1052 of the restriction path 1050 may have any desired depth or width to achieve the desired flow restriction. In some implementations, the cross-sections of the passages 1052 may differ.

The passages 1052 extend from the circumferential groove 1046 along a helical path, but in other implementations the passages 1052 may extend straight from the circumferential groove 1046 to the second end 1034 or may have a path which takes a zig-zag or other path as desired. The passages 1052 have a constant cross-sectional profile along the longitudinal axis B-B but need not have a constant profile in all implementations. The cross-sectional profile may vary, tapering or having non-linear variations along the length of the flow restrictor 1030 from the circumferential groove 1046 to the second end 1034. Preferably, the cross-sectional area and the length of the passages are selected to achieve laminar flow. Above certain ratios of area to length (greater area per length), the flow becomes turbulent and is no longer laminar, so these ratios are to be avoided. Where additional area is required to achieve the desired flow restriction, additional passages may be added in lieu of increasing the area of a single passage.

### Exemplary claim Set

Exemplary claim 1: A system for processing articles comprising: a fluid supply; an apparatus for controlling flow fluidly coupled to the fluid supply, the apparatus for controlling flow comprising: a body comprising a flow path extending from an inlet to an outlet; a valve operably coupled to the flow path between the inlet and the outlet, the valve configured to alter fluid flow within the flow path, the valve comprising a seat and a closure member; a flow restrictor having a flow impedance located within the flow path, the flow restrictor comprising: a restriction path extending from a first end to a second end along a longitudinal axis; a circumferential groove; and a longitudinal groove extending from the circumferential groove to the first end; and a pressure sensor configured to measure pressure within a volume between the seat of the valve and the flow restrictor; and a processing chamber fluidly coupled to the outlet of the apparatus for controlling flow, the processing chamber configured to process semiconductor devices.

Exemplary claim 2: The system of exemplary claim 1 wherein the pressure sensor is configured to sense a pressure within the circumferential groove.

Exemplary claim 3: The system of exemplary claim 1 or exemplary claim 2 wherein the longitudinal groove provides fluid communication between the volume and the circumferential groove.

Exemplary claim 4: The system of any one of exemplary claims 1 to 3 wherein the flow restrictor comprises a plurality of longitudinal grooves circumferentially spaced about the flow restrictor.

Exemplary claim 5: The system of any one of exemplary claims 1 to 4 wherein the longitudinal groove is parallel to the longitudinal axis.

Exemplary claim 6: The system of any one of exemplary claims 1 to 5 wherein the first end of the flow restrictor is immediately adjacent to the seat of the valve.

Exemplary claim 7: The system of any one of exemplary claims 1 to 6 wherein the first end of the flow restrictor is concave.

Exemplary claim 8: The system of any one of exemplary claims 1 to 7 wherein the circumferential groove is proximate the first end.

Exemplary claim 9: The system of any one of exemplary claims 1 to 8 wherein the circumferential groove has a first radial depth and the longitudinal groove has a second radial depth, the first radial depth greater than the second radial depth.

Exemplary claim 10: The system of any one of exemplary claims 1 to 9 wherein the circumferential groove has a first cross-sectional area and the longitudinal groove has a second cross-sectional area, the first cross-sectional area greater than the second cross-sectional area.

Exemplary claim 11: The system of any one of exemplary claims 1 to 10 wherein the restriction path comprises a plurality of branched portions as viewed transverse to the longitudinal axis.

Exemplary claim 12: The system of exemplary claim 11 wherein the branched portions are symmetrical about the longitudinal axis.

Exemplary claim 13: The system of exemplary claim 11 or exemplary claim 12 wherein the branched portions comprise a plurality of slots having equal width when viewed in cross-section.

Exemplary claim 14: The system of any one of exemplary claims 11 to 13 wherein the branched portions each comprise a plurality of slots.

Exemplary claim 15: The system of any one of exemplary claims 1 to 10 wherein the restriction path comprises a plurality of passages.

Exemplary claim 16: The system of exemplary claim 15 wherein the flow restrictor comprises an outer ring and a first inner ring, the plurality of passages formed by an outer surface of the first inner ring and an inner surface of the outer ring.

Exemplary claim 17: The system of exemplary claim 16 wherein the first inner ring is a cylinder comprising a plurality of grooves formed into the outer surface of the first inner ring.

Exemplary claim 18: The system of exemplary claim 15 wherein the flow restrictor comprises an outer ring and a plurality of inner rings, a first one of the plurality of passages formed between the outer ring and a first one of the plurality of inner rings and a second one of the plurality of passages formed between the first one of the plurality of inner rings and a second one of the plurality of inner rings.

Exemplary claim 19: The system of exemplary claim 18 wherein the plurality of inner rings comprises a cylinder, the cylinder surrounded by the second one of the plurality of inner rings, the second one of the plurality of inner rings surrounded by the first one of the plurality of inner rings, and the first one of the plurality of inner rings surrounded by the outer ring.

Exemplary claim 20: The system of any one of exemplary claims 1 to 10 wherein the restriction path comprises a passage extending from the circumferential groove to the second end.

Exemplary claim 21: The system of exemplary claim 20 wherein the restriction path comprises a plurality of passages extending from the circumferential groove to the second end.

Exemplary claim 22: The system of exemplary claim 20 or exemplary claim 21 wherein the passage follows a helical path.

Exemplary claim 23: The system of any one of exemplary claims 20 to 22 wherein the passage extends along an outer surface of the flow restrictor.

Exemplary claim 24: An apparatus for controlling flow comprising: a body comprising a flow path extending from an inlet to an outlet; a valve operably coupled to the flow path between the inlet and the outlet, the valve configured to alter fluid flow within the flow path, the valve comprising a seat and a closure member; a flow restrictor having a flow impedance located within the flow path, the flow restrictor comprising: a restriction path extending from a first end to a second end along a longitudinal axis; a circumferential groove; and a longitudinal groove extending from the circumferential groove to the first end; and a pressure sensor configured to measure pressure within a volume between the seat of the valve and the flow restrictor.

Exemplary claim 25: The apparatus of exemplary claim 24 wherein the pressure sensor is configured to sense a pressure within the circumferential groove.

Exemplary claim 26: The apparatus of exemplary claim 24 or exemplary claim 25 wherein the longitudinal groove provides fluid communication between the volume and the circumferential groove.

Exemplary claim 27: The apparatus of any one of exemplary claims 24 to 26 wherein the flow restrictor comprises a plurality of longitudinal grooves circumferentially spaced about the flow restrictor.

Exemplary claim 28: The apparatus of any one of exemplary claims 24 to 27 wherein the longitudinal groove is parallel to the longitudinal axis.

Exemplary claim 29: The apparatus of any one of exemplary claims 24 to 28 wherein the first end of the flow restrictor is immediately adjacent to the seat of the valve.

Exemplary claim 30: The apparatus of any one of exemplary claims 24 to 29 wherein the first end of the flow restrictor is concave.

Exemplary claim 31: The apparatus of any one of exemplary claims 24 to 30 wherein the circumferential groove is proximate the first end.

Exemplary claim 32: The apparatus of any one of exemplary claims 24 to 31 wherein the circumferential groove has a first radial depth and the longitudinal groove has a second radial depth, the first radial depth greater than the second radial depth.

Exemplary claim 33: The apparatus of any one of exemplary claims 24 to 32 wherein the circumferential groove has a first cross-sectional area and the longitudinal groove has a second cross-sectional area, the first cross-sectional area greater than the second cross-sectional area.

Exemplary claim 34: The apparatus of any one of exemplary claims 24 to 33 wherein the restriction path comprises a plurality of branched portions as viewed transverse to the longitudinal axis.

Exemplary claim 35: The apparatus of exemplary claim 34 wherein the branched portions are symmetrical about the longitudinal axis.

Exemplary claim 36: The apparatus of exemplary claim 34 or exemplary claim 35 wherein the branched portions comprise a plurality of slots having equal width when viewed in cross-section.

Exemplary claim 37: The apparatus of any one of exemplary claims 34 to 36 wherein the branched portions each comprise a plurality of slots.

Exemplary claim 38: The apparatus of any one of exemplary claims 34 to 37 wherein the restriction path comprises a plurality of passages.

Exemplary claim 39: The apparatus of exemplary claim 38 wherein the flow restrictor comprises an outer ring and a first inner ring, the plurality of passages formed by an outer surface of the first inner ring and an inner surface of the outer ring.

Exemplary claim 40: The apparatus of exemplary claim 39 wherein the first inner ring is a cylinder comprising a plurality of grooves formed into the outer surface of the first inner ring.

Exemplary claim 41: The apparatus of exemplary claim 38 wherein the flow restrictor comprises an outer ring and a plurality of inner rings, a first one of the plurality of passages formed between the outer ring and a first one of the plurality of inner rings and a second one of the plurality of passages formed between the first one of the plurality of inner rings and a second one of the plurality of inner rings.

Exemplary claim 42: The apparatus of exemplary claim 41 wherein the plurality of inner rings comprises a cylinder, the cylinder surrounded by the second one of the plurality of inner rings, the second one of the plurality of inner rings surrounded by the first one of the plurality of inner rings, and the first one of the plurality of inner rings surrounded by the outer ring.

Exemplary claim 43: The apparatus of any one of claims 24 to 33 wherein the restriction path comprises a passage extending from the circumferential groove to the second end.

Exemplary claim 44: The apparatus of claim 43 wherein the passage follows a helical path.

Exemplary claim 45: The apparatus of claim 43 or claim 44 wherein the passage extends along an outer surface of the flow restrictor.

Exemplary claim 46: The apparatus of any one of claims 24 to 33 wherein the restriction path comprises a plurality of passages extending from the circumferential groove to the second end.

Exemplary claim 47: A flow restrictor for controlling flow comprising: a body extending from a first end to a second end along a longitudinal axis, the body comprising an outer surface having a sealing portion configured to engage a passage of a valve; and a restriction path extending from the first end to the second end along the longitudinal axis.

Exemplary claim 48: The flow restrictor of exemplary claim 47 wherein the restriction path is formed within the body, no portion of the restriction path extending to the outer surface.

Exemplary claim 49: The flow restrictor of exemplary claim 47 or exemplary claim 48 wherein the restriction path comprises a plurality of branched portions as viewed transverse to the longitudinal axis.

Exemplary claim 50: The flow restrictor of exemplary claim 49 wherein the branched portions are symmetrical about the longitudinal axis.

Exemplary claim 51: The flow restrictor of exemplary claim 49 or exemplary claim 50 wherein the branched portions comprise a plurality of slots having equal width when viewed in cross-section.

Exemplary claim 52: The flow restrictor of any one of exemplary claims 49 to 51 wherein the branched portions each comprise a plurality of slots.

Exemplary claim 53: The flow restrictor of any one of exemplary claims 49 to 52 wherein the restriction path comprises a plurality of passages.

Exemplary claim 54: The flow restrictor of exemplary claim 53 wherein the flow restrictor comprises an outer ring and a first inner ring, the plurality of passages formed by an outer surface of the first inner ring and an inner surface of the outer ring.

Exemplary claim 55: The flow restrictor of exemplary claim 54 wherein the first inner ring is a cylinder comprising a plurality of grooves formed into the outer surface of the first inner ring.

Exemplary claim 56: The flow restrictor of exemplary claim 53 wherein the flow restrictor comprises an outer ring and a plurality of inner rings, a first one of the plurality of passages formed between the outer ring and a first one of the plurality of inner rings and a second one of the plurality of passages formed between the first one of the plurality of inner rings and a second one of the plurality of inner rings.

Exemplary claim 57: The flow restrictor of exemplary claim 56 wherein the plurality of inner rings comprises a cylinder, the cylinder surrounded by the second one of the plurality of inner rings, the second one of the plurality of inner rings surrounded by the first one of the plurality of inner rings, and the first one of the plurality of inner rings surrounded by the outer ring.

Exemplary claim 58: The flow restrictor of any one of exemplary claims 47 to 57 wherein the flow restrictor comprises a circumferential groove formed into the outer surface and a longitudinal groove extending from the circumferential groove to the first end.

Exemplary claim 59: The apparatus of exemplary claim 58 wherein the longitudinal groove is configured to provide fluid communication between the first end and the circumferential groove when the flow restrictor is positioned within a bore of a valve.

Exemplary claim 60: The flow restrictor of exemplary claim 58 or exemplary claim 59 comprising a plurality of longitudinal grooves circumferentially spaced about the flow restrictor.

Exemplary claim 61: The flow restrictor of any one of exemplary claims 58 to 60 wherein the longitudinal groove is parallel to the longitudinal axis.

Exemplary claim 62: The flow restrictor of any one of exemplary claims 58 to 61 wherein the first end of the flow restrictor is immediately adjacent to the seat of the valve.

Exemplary claim 63: The flow restrictor of any one of exemplary claims 58 to 62 wherein the first end of the flow restrictor is concave.

Exemplary claim 64: The flow restrictor of any one of exemplary claims 58 to 63 wherein the circumferential groove is proximate the first end.

Exemplary claim 65: The flow restrictor of any one of exemplary claims 58 to 64 wherein the circumferential groove has a first radial depth and the longitudinal groove has a second radial depth, the first radial depth greater than the second radial depth.

Exemplary claim 66: The flow restrictor of any one of exemplary claims 58 to 65 wherein the circumferential groove has a first cross-sectional area and the longitudinal groove has a second cross-sectional area, the first cross-sectional area greater than the second cross-sectional area.

Exemplary claim 67: The flow restrictor of claim 47 wherein the restriction path comprises a passage extending from the circumferential groove to the second end.

Exemplary claim 68: The flow restrictor of claim 67 wherein the passage follows a helical path.

Exemplary claim 69: The flow restrictor of claim 67 or claim 68 wherein the passage extends along an outer surface of the flow restrictor.

Exemplary claim 70: The flow restrictor of any one of claims 67 to 69 wherein the restriction path comprises a plurality of passages extending from the circumferential groove to the second end.

While the invention has been described with respect to specific examples including presently preferred modes of carrying out the invention, those skilled in the art will appreciate that there are numerous variations and permutations of the above described systems and techniques. It is to be understood that other embodiments may be utilized, and structural and functional modifications may be made without departing from the scope of the present invention. Thus, the spirit and scope of the invention should be construed broadly as set forth in the appended claims.

1. A system for processing articles comprising:
a fluid supply;
an apparatus for controlling flow fluidly coupled to the fluid supply, the apparatus for controlling flow comprising:
a body comprising a flow path extending from an inlet to an outlet;
a valve operably coupled to the flow path between the inlet and the outlet, the valve configured to alter fluid flow within the flow path, the valve comprising a seat and a closure member;
a flow restrictor having a flow impedance located within the flow path, the flow restrictor comprising:
a restriction path extending from a first end to a second end along a longitudinal axis;
a circumferential groove; and
a longitudinal groove extending from the circumferential groove to the first end; and
a pressure sensor configured to measure pressure within a volume between the seat of the valve and the flow restrictor; and
a processing chamber fluidly coupled to the outlet of the apparatus for controlling flow, the processing chamber configured to process semiconductor devices.

2. The system of claim 1 wherein the pressure sensor is configured to sense a pressure within the circumferential groove.

3. The system of claim 1 wherein the longitudinal groove provides fluid communication between the volume and the circumferential groove.

4. The system of claim 1 wherein the flow restrictor comprises a plurality of longitudinal grooves circumferentially spaced about the flow restrictor.

5. The system of claim 1 wherein the longitudinal groove is parallel to the longitudinal axis.

6. The system of claim 1 wherein the first end of the flow restrictor is immediately adjacent to the seat of the valve.

7. The system of claim 1 wherein the first end of the flow restrictor is concave.

8. The system of claim 1 wherein the circumferential groove is proximate the first end.

9. The system of claim 1 wherein the circumferential groove has a first radial depth and the longitudinal groove has a second radial depth, the first radial depth greater than the second radial depth.

10. The system of claim 1 wherein the circumferential groove has a first cross-sectional area and the longitudinal groove has a second cross-sectional area, the first cross-sectional area greater than the second cross-sectional area.

11-23. (canceled)

24. An apparatus for controlling flow comprising:
a body comprising a flow path extending from an inlet to an outlet;
a valve operably coupled to the flow path between the inlet and the outlet, the valve configured to alter fluid flow within the flow path, the valve comprising a seat and a closure member;
a flow restrictor having a flow impedance located within the flow path, the flow restrictor comprising:
a restriction path extending from a first end to a second end along a longitudinal axis;
a circumferential groove; and
a longitudinal groove extending from the circumferential groove to the first end; and
a pressure sensor configured to measure pressure within a volume between the seat of the valve and the flow restrictor.

25. The apparatus of claim 24 wherein the pressure sensor is configured to sense a pressure within the circumferential groove.

26. The apparatus of claim 24 wherein the longitudinal groove provides fluid communication between the volume and the circumferential groove.

27-46. (canceled)

47. A flow restrictor for controlling flow comprising:
a body extending from a first end to a second end along a longitudinal axis, the body comprising an outer surface having a sealing portion configured to engage a passage of a valve; and
a restriction path extending from the first end to the second end along the longitudinal axis.

48. The flow restrictor of claim 47 wherein the restriction path is formed within the body, no portion of the restriction path extending to the outer surface.

49. The flow restrictor of claim 47 wherein the restriction path comprises a plurality of branched portions as viewed transverse to the longitudinal axis, wherein the branched portions comprise a plurality of slots having equal width when viewed in cross-section, and wherein the restriction path comprises a plurality of passages.

50-53. (canceled)

54. The flow restrictor of claim 47 wherein the restriction path comprises a plurality of passages, and wherein the flow restrictor comprises an outer ring and a first inner ring, the plurality of passages formed by an outer surface of the first inner ring and an inner surface of the outer ring.

55. (canceled)

56. The flow restrictor of claim 47 wherein the restriction path comprises a plurality of passages, and wherein the flow restrictor comprises an outer ring and a plurality of inner rings, a first one of the plurality of passages formed between the outer ring and a first one of the plurality of inner rings and a second one of the plurality of passages formed between the first one of the plurality of inner rings and a second one of the plurality of inner rings.

57. The flow restrictor of claim 56 wherein the plurality of inner rings comprises a cylinder, the cylinder surrounded by the second one of the plurality of inner rings, the second one of the plurality of inner rings surrounded by the first one of the plurality of inner rings, and the first one of the plurality of inner rings surrounded by the outer ring.

58. The flow restrictor of claim 47 wherein the flow restrictor comprises a circumferential groove formed into the outer surface and a longitudinal groove extending from the circumferential groove to the first end.

59-70. (canceled)
